(19) United States
(12) Patent Application Publication
(10) Pub. No.: US 2026/0049873 A1
(43) Pub. Date: Feb. 19, 2026

(54) THERMAL ANNEALING CALIBRATION USING MICROFABRICATED RESISTANCE TEMPERATURE SENSORS

(71) Applicant: International Business Machines Corporation, Armonk, NY (US)

(72) Inventors: Charles Thomas Rettner, San Jose, CA (US); Russell A. Budd, North Salem, NY (US); Eric Zhang, Sleepy Hollow, NY (US); Bucknell C Webb, Ossining, NY (US)

(21) Appl. No.: 18/804,401

(22) Filed: Aug. 14, 2024

(51) Int. Cl. G01K 7/16; C21D 1/26; C21D 1/34; C21D 9/00

(52) U.S. Cl. CPC G01K 7/16; C21D 1/26; C21D 1/34; C21D 9/0068

(57) ABSTRACT

Techniques are provided for calibrating thermal annealing processes (e.g., laser annealing) using microfabricated resistance temperature sensors. For example, a device comprises a substrate, and a resistance temperature sensor disposed on the substrate. The resistance temperature sensor comprises a stack of alternating metal layers of a first metal and a second metal, wherein the first metal and the second metal are different types of metals.

### BACKGROUND

This disclosure relates generally to techniques for calibrating thermal annealing processes such as laser annealing processes that utilize laser beams to heat and modify materials and components of integrated circuits. In the context of quantum computing systems, superconducting tunnel junction devices (e.g., Josephson junctions) are key components of quantum devices such as superconducting quantum bits (qubits). A Josephson junction is a non-linear device (with a non-linear inductance) which comprises two superconducting electrodes separated by a thin insulating barrier layer. In general, qubits are fabricated with at least one capacitor shunted with a Josephson junction, to form an anharmonic oscillator with individually addressable quantized computational basis states (e.g., a ground state |0) and a first excited state |1)). A fixed-frequency qubit, such as a transmon qubit, has a transition frequency (denoted f₀₁) which corresponds to an energy difference between a ground state |0) and a first excited state |1) of the qubit. It is known that the transition frequency f₀₁ of a qubit can be estimated from a normal state resistance (denoted Rn) of the Josephson junction of the qubit.

The efficient design of quantum circuits using qubits requires precise control of the transition frequencies of qubits, as frequency crowding and frequency collisions are a major challenge in scaling quantum computers to larger numbers of qubits having Josephson junctions. Of particular concern is the need to control the junction resistance Rn of a Josephson junction of a qubit since the junction resistance Rn determines the transition frequency of the qubit. The junction resistance Rn of a Josephson junction may be adjusted by heating (annealing) the junction with a high-power laser. To accurately reach a target junction resistance, various parameters of the laser annealing process, such as laser power, exposure time, illumination pattern, and laser-to-junction alignment, etc., should be precisely controlled.

### SUMMARY

Exemplary embodiments of the disclosure include techniques for calibrating thermal annealing processes (e.g., laser annealing) using microfabricated resistance temperature sensors.

For example, an exemplary embodiment includes a device which comprises a substrate, and a resistance temperature sensor disposed on the substrate. The resistance temperature sensor comprises a stack of alternating metal layers of a first metal and a second metal, wherein the first metal and the second metal are different types of metals.

Another exemplary embodiment includes a method which comprises: selecting a laser beam illumination pattern and a first laser power setting to irradiate a test structure disposed on a substrate, wherein the test structure emulates a geometric structure of a quantum device comprising a Josephson junction, and comprises a resistance temperature sensor that emulates a size and placement of the Josephson junction of the quantum device; performing a first thermal anneal process by irradiating the test structure using the selected laser beam illumination pattern at the first laser power setting to thermally anneal the resistance temperature sensor; measuring a first resistance of the resistance temperature sensor subsequent to the first thermal anneal process; and determining a maximum temperature to which the resistance temperature sensor was exposed as a result of the first thermal anneal process, based on the measured first resistance.

Another exemplary embodiment includes a method which comprises: selecting a laser beam illumination pattern and a laser power setting to irradiate a test structure disposed on a substrate, wherein the test structure emulates a geometric structure of a quantum device comprising a Josephson junction, and comprises a resistance temperature sensor that emulates a size and placement of the Josephson junction of the quantum device; performing a thermal anneal process by irradiating the test structure using the selected laser beam illumination pattern at the laser power setting to thermally anneal the resistance temperature sensor; measuring a resistance of the resistance temperature sensor subsequent to the thermal anneal process; determining a maximum temperature to which the resistance temperature sensor was exposed as a result of the thermal anneal process, based on the measured resistance; obtaining a simulated thermal profile which represents a temperature gradient of a substrate surface irradiated using the selected laser beam illumination pattern and the laser power setting; utilizing the simulated thermal profile to estimate a maximum temperature at a region of the substrate where the resistance temperature sensor of the test structure is located; comparing the estimated maximum temperature with the determined maximum temperature; and determining an accuracy of the simulated thermal profile, based on a result of comparing the estimated maximum temperature with the determined maximum temperature.

Other embodiments will be described in the following detailed description of exemplary embodiments, which is to be read in conjunction with the accompanying figures.

### BRIEF DESCRIPTION OF THE DRAWINGS

FIGS. 1A and 1B schematically illustrate a resistance temperature sensor, according to an exemplary embodiment of the disclosure.

FIG. 2 is a graph which illustrates resistance as a function of temperature of a resistance temperature sensor, according to an exemplary embodiment of the disclosure.

FIGS. 3A and 3B schematically illustrate a thermal annealing system, according to an exemplary embodiment of the disclosure.

FIG. 4 illustrates a flow diagram of a method for performing a resistance temperature sensor calibration process, according to an exemplary embodiment of the disclosure.

FIG. 5 schematically illustrates a method for measuring a resistance of a resistance temperature sensor, according to an exemplary embodiment of the disclosure.

FIGS. 6A, 6B, 6C, 6D, 6E, and 6F schematically illustrate various exemplary modes of operation of a laser annealing system to generate structured laser beam illumination patterns, according to exemplary embodiments of the disclosure, wherein:

FIG. 6A schematically illustrates a method for generating a structured laser beam illumination pattern;

FIG. 6B schematically illustrates a method for adjusting a laser beam spot size using a variable beam expander of a laser microscope unit, according to an exemplary embodiment of the disclosure;

FIG. 6C schematically illustrates a method for generating different laser beam illumination patterns using a linear array of laser beam shaping diffractive optical elements of a laser microscope unit, according to an exemplary embodiment of the disclosure;

FIG. 6D schematically illustrates laser beam illumination patterns having different spot patterns and spot pitches between laser spots;

FIG. 6E schematically illustrates a process for generating a dual laser beam spot pattern having Gaussian laser beam spots; and

FIG. 6F schematically illustrates a process for generating a dual laser beam spot pattern having annular laser beam spots.

FIGS. 7A and 7B schematically illustrate an exemplary quantum device comprising a Josephson junction, and a corresponding test structure of the quantum device of FIG. 7A with a resistance temperature sensor emulating a size and layout of the Josephson junction of the quantum device, according to exemplary embodiment of the disclosure.

FIGS. 8A and 8B schematically illustrate an exemplary quantum device comprising a Josephson junction, and a corresponding test structure of the quantum device of FIG. 8A with a resistance temperature sensor emulating a size and layout of the Josephson junction of the quantum device, according to another exemplary embodiment of the disclosure.

FIGS. 9A, 9B, 9C, 9D, 9E, 9F, and 9G schematically illustrate methods for laser annealing resistance temperature sensors of the exemplary test structures of FIGS. 7B and 8B using various structured laser beam illumination patterns, according to exemplary embodiments of the disclosure.

FIG. 10 illustrates a flow diagram of a method for performing a calibration process to determine thermal profiles of structured laser beam illumination patterns, according to an exemplary embodiment of the disclosure.

FIG. 11 illustrates a calibration curve that represents resistance as a function of temperature for a given structured laser beam illumination pattern, according to an exemplary embodiment of the disclosure.

FIG. 12 is a graph which illustrates a plurality of calibration curves that represent resistance as a function of power level setting for a plurality of unique structured laser beam illumination patterns, according to an exemplary embodiment of the disclosure.

FIGS. 13A and 13B illustrate a simulated thermal profile of a structured laser beam illumination pattern, according to an exemplary embodiment of the disclosure.

FIG. 14 is a graph which compares a measured laser power to a simulated laser power for different structured laser beam illumination patterns, according to an exemplary embodiment of the disclosure.

FIG. 15 illustrates a flow diagram of a method to compare and verify a simulated thermal profile and a corresponding measured thermal profile for a given structured laser beam illumination pattern at a given power level, according to an exemplary embodiment of the disclosure.

FIG. 16 schematically illustrates an exemplary architecture of a computing environment for implementing a control system of a thermal annealing system, according to an exemplary embodiment of the disclosure.

### DETAILED DESCRIPTION

Exemplary embodiments of the disclosure will now be described in further detail with regard to techniques for calibrating thermal annealing processes (e.g., laser annealing) using microfabricated resistance temperature sensors.

An exemplary embodiment includes a device which comprises a substrate, and a resistance temperature sensor disposed on the substrate. The resistance temperature sensor comprises a stack of alternating metal layers of a first metal and a second metal, wherein the first metal and the second metal are different types of metals.

In another exemplary embodiment, which may be combined with one or more of the embodiments of the preceding paragraphs, the metal layers of the first metal have a first thickness, and the metal layers of the second metal have a second thickness, where the first thickness is less than the second thickness.

In another exemplary embodiment, which may be combined with one or more of the embodiments of the preceding paragraphs, the first metal comprises titanium, and the second metal comprises platinum.

In another exemplary embodiment, which may be combined with one or more of the embodiments of the preceding paragraphs, the resistance temperature sensor comprises a resistive wire. The resistive wire comprises a first wire portion, a second wire portion, and a third wire portion disposed between the first wire portion and the second wire portion. The first wire portion and the second wire portion have a first width. The third wire portion comprises a second width, which is less than the first width.

In another exemplary embodiment, which may be combined with one or more of the embodiments of the preceding paragraphs, the resistance temperature sensor comprises a negative temperature coefficient in which an electrical resistance of the resistance temperature sensor decreases as the resistance temperature sensor is heated at increasing temperatures.

In another exemplary embodiment, which may be combined with one or more of the embodiments of the preceding paragraphs, the resistance temperature sensor comprises at least three metal layers of the first metal and three metal layers of the second metal.

In another exemplary embodiment, which may be combined with one or more of the embodiments of the preceding paragraphs, the resistance temperature sensor is a component of a test structure that is disposed on the substrate. The test structure emulates a geometric structure of a quantum device comprising a Josephson junction, and the resistance temperature sensor emulates a size and placement of the Josephson junction of the quantum device.

In another exemplary embodiment, which may be combined with one or more of the embodiments of the preceding paragraphs, the quantum device comprises a superconducting quantum bit.

Another exemplary embodiment includes a method for thermal anneal calibration. A laser beam illumination pattern and a first laser power setting are selected to irradiate a test structure disposed on a substrate, where the test structure emulates a geometric structure of a quantum device comprising a Josephson junction, where the test structure comprises a resistance temperature sensor that emulates a size and placement of the Josephson junction of the quantum device. A first thermal anneal process is performed by irradiating the test structure using the selected laser beam illumination pattern at the first laser power setting to thermally anneal the resistance temperature sensor. A first resistance of the resistance temperature sensor is measured subsequent to the first thermal anneal process. A maximum temperature to which the resistance temperature sensor was exposed as a result of the first thermal anneal process, is determined based on the measured first resistance.

In another exemplary embodiment, which may be combined with one or more of the embodiments of the preceding paragraphs, the method further comprises: increasing a laser power of the selected laser beam illumination pattern to a second laser power setting; performing a second thermal anneal process by irradiating the test structure using the selected laser beam illumination pattern at the second laser power setting to thermally anneal the resistance temperature sensor; measuring a second resistance of the resistance temperature sensor subsequent to the second thermal anneal process; and determining a maximum temperature to which the resistance temperature sensor was exposed as a result of the second thermal anneal process, based on the measured second resistance.

In another exemplary embodiment, which may be combined with one or more of the embodiments of the preceding paragraphs, the method further comprises utilizing at least the measured first resistance and the measured second resistance to generate a calibration curve that represents a resistance of the resistance temperature sensor as a function of the laser power of the selected laser beam illumination pattern.

In another exemplary embodiment, which may be combined with one or more of the embodiments of the preceding paragraphs, the method further comprises persistently storing the calibration curve for subsequent use in configuring a laser annealing process to laser anneal a quantum device that is emulated by the test structure.

In another exemplary embodiment, which may be combined with one or more of the embodiments of the preceding paragraphs, selecting the laser beam illumination pattern comprises selecting a combination of parameters for generating the laser beam illumination pattern, where the parameters comprise a laser spot pattern, a laser spot size, a laser spot pitch, and a laser spot profile.

In another exemplary embodiment, which may be combined with one or more of the embodiments of the preceding paragraphs, the laser spot pattern comprises a single-spot pattern, a dual-spot pattern, a triple-spot pattern, or a quad-spot pattern. The laser spot profile comprises an annular profile or a Gaussian profile.

In another exemplary embodiment, which may be combined with one or more of the embodiments of the preceding paragraphs, test structure emulates a geometric structure of superconducting qubit comprising at least one Josephson junction.

Another exemplary embodiment includes a method for thermal anneal calibration. A laser beam illumination pattern and a laser power setting are selected to irradiate a test structure disposed on a substrate, where the test structure emulates a geometric structure of a quantum device comprising a Josephson junction, and where the test structure comprises a resistance temperature sensor that emulates a size and placement of the Josephson junction of the quantum device. A thermal anneal process is performed by irradiating the test structure using the selected laser beam illumination pattern at the laser power setting to thermally anneal the resistance temperature sensor. A resistance of the resistance temperature sensor is measured subsequent to the thermal anneal process. A maximum temperature to which the resistance temperature sensor was exposed as a result of thermal anneal process, is determined based on the measured first resistance. A simulated thermal profile is obtained, which represents a temperature gradient of a substrate surface irradiated using the selected laser beam illumination pattern and the laser power setting. The simulated thermal profile is utilized to estimate a maximum temperature at a region of the substrate where the resistance temperature sensor of the test structure is located. The estimated maximum temperature is compared with the determined maximum temperature. An accuracy of the simulated thermal profile is determined based on a result of comparing the estimated maximum temperature with the determined maximum temperature.

In another exemplary embodiment, which may be combined with one or more of the embodiments of the preceding paragraphs, the method further comprises persistently storing the simulated thermal profile in association with the selected laser beam illumination pattern and the laser power setting for subsequent use in configuring a laser annealing process to laser anneal a quantum device that is emulated by the test structure.

In another exemplary embodiment, which may be combined with one or more of the embodiments of the preceding paragraphs, the method further comprises obtaining an updated simulated thermal profile which represents a temperature gradient of a substrate surface irradiated using the selected laser beam illumination pattern and the laser power setting, based on at least one updated thermal model parameter.

In another exemplary embodiment, which may be combined with one or more of the embodiments of the preceding paragraphs, selecting the laser beam illumination pattern comprises selecting a combination of parameters for generating the laser beam illumination pattern, where the parameters comprise a laser spot pattern, a laser spot size, a laser spot pitch, and a laser spot profile. The laser spot pattern comprises a single-spot pattern, a dual-spot pattern, a triple-spot pattern, or a quad-spot pattern. The laser spot profile comprises an annular profile or a Gaussian profile.

In another exemplary embodiment, which may be combined with one or more of the embodiments of the preceding paragraphs, the test structure emulates a geometric structure of superconducting qubit comprising at least one Josephson junction.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. To provide spatial context to the different structural orientations of the structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

Further, the term “exemplary” as used herein means serving as an example, instance, or illustration. Any embodiment or design described herein as “exemplary” is not to be construed as preferred or advantageous over other embodiments or designs. In addition, the terms “about” or “substantially” as used herein with regard to, e.g., percentages, ranges, etc., are meant to denote being close or approximate to, but not exactly. For example, the term “about” or “substantially” as used herein implies that a small margin of error may be present, such as 1% or less than the stated amount.

It is to be further understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

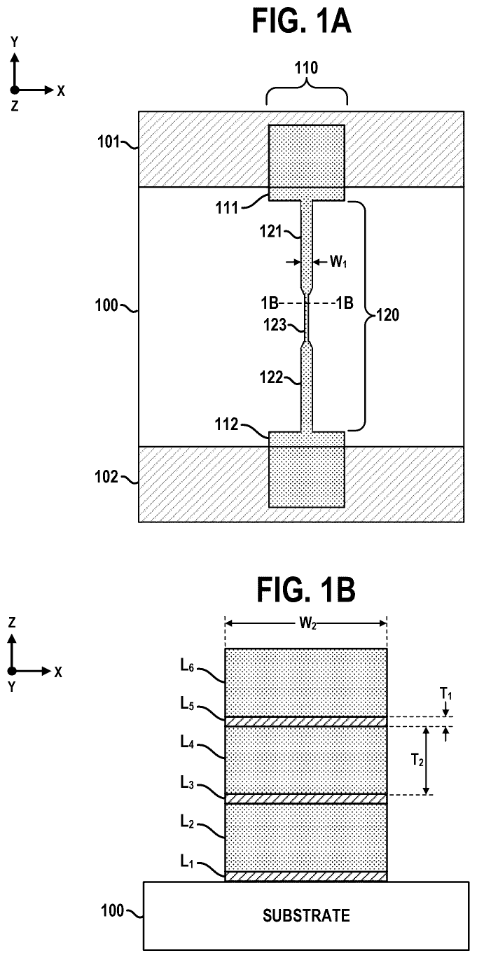

FIGS. 1A and 1B schematically illustrate a resistance temperature sensor, according to an exemplary embodiment of the disclosure. FIG. 1A is a schematic top plan view of an exemplary architecture and layout of a microfabricated resistance temperature sensor that is formed on a substrate, and FIG. 1B is a schematic cross-sectional view along line 1B-1B in FIG. 1A. In particular, FIG. 1A schematically illustrates a portion of substrate 100 comprising a first electrode 101 and a second electrode 102 formed on a surface of the substrate 100, and a microfabricated resistance temperature sensor 110 (also referred to as “resistance temperature sensor 110”) which is formed on the surface of the substrate 100 between and in contact with the first and second electrodes 101 and 102. The resistance temperature sensor 110 comprises a first contact pad 111, a second contact pad 112, and a resistive wire 120 disposed between and in contact with the first and second contact pads 111 and 112. The resistive wire 120 comprises a first wire portion 121, a second wire portion 122, and a third wire portion 123. The first and second wire portions 121 and 122 have widths that are greater than a width of the third wire portion 123. In some embodiments, the resistance temperature sensor 110 comprises a stacked structure comprising multiple alternating thin-film layers of a first metal and a second metal, wherein the first metal and the second metal are different types of metals.

For example, as schematically shown in FIG. 1B, in some embodiments, the resistive temperature sensor 110 comprises a stack of thin-film metal layers L₁, L₂, L₃, L₄, L₅, and L₆. In some embodiments, the thin-film metal layers L₁, L₃, and L₅ are formed of a first type of metal material, and the thin-film metal layers L₂, L₄, and L₆ are formed of a second type of metal material. For example, in some embodiments, the first type of metal material comprises titanium (Ti), and the second type of metal material comprises platinum (Pt). Moreover, in some embodiments, the thin-film metal layers L₁, L₃, and L₅ are formed to have a first thickness T₁, and the thin-film metal layers L₂, L₄, and L₆ are formed to have a second thickness T₂, where T₂>T₁. For example, in some embodiments, the thin-film metal layers L₁, L₃, and L₅ comprise thin-film Ti layers with a same nominal thickness T₁ of about 5 nanometers (nm), and the thin-film metal layers L₂, L₄, and L₆ comprise thin-film Pt layers with a same nominal thickness T₂ of about 30 nm.

The resistance temperature sensor 110 comprises an initial resistance after fabrication. In particular, the stack of thin-film metal layers L₁, L₂, L₃, L₄, L₅, and L₆ has an initial resistance (or conversely, initial conductance) where current can flow through the separate thin-film metal layers L₁, L₂, L₃, L₄, L₅, and L₀, wherein the total conductance is essentially equal to conductance of each thin-film metal layer added in parallel, less a term due to conduction loss caused by as a result of scattering at the interfaces between adjacent layers of the stack of thin-film metal layers L₁, L₂, L₃, L₄, L₅, and L₆. More specifically, each thin-film metal layer L₁, L₂, L₃, L₄, L₅, and L₆ will have a corresponding sheet resistance R_{S} as deposited, wherein the sheet resistance R_{S} of a given thin-film metal layer is determined as: R_{S}=ρ/T, where ρ denotes the electrical resistivity of the metal material of the given metal layer, and where T denotes the thickness of the given metal layer. For a given thin-film metal layer having a constant sheet resistance R_{S} and thickness T, the resistance R of a given portion of the metal layer is determined as: R=R_{S}×L/W, where L and W denote the length and width of the given portion of the thin-film metal layer.

As schematically illustrated in FIGS. 1A and 1B, the resistive wire 120 disposed between the first and second contact pads 111 and 112 has different widths. In particular, the first wire portion 121 and the second wire portion 122 have a first width W₁, while the third wire portion 123 has a second width W₂, wherein W₂<W₁. For example, in a non-limiting exemplary embodiment, W₁ is 1.0 micron, and W₂ is 0.5 micron. Although the first, second, and third wire portions 121, 122, and 123 have the same stack of thin-film metal layers L₁, L₂, L₃, L₄, L₅, and L₆ as shown in FIG. 1B, the first, second, and third wire portions 121, 122, and 123 will have different resistances that contribute to the total resistance measured across the resistance temperature sensor 110, since the first, second, and third wire portions 121, 122, and 123 have different geometries (e.g., widths and lengths). As noted above, for a given thin-film metal layer having a constant sheet resistance R_{S} and thickness T, the resistance of a given portion of the given thin-film metal layer is proportional to the length L and inversely proportional to the width W of the given metal layer. Therefore, the thinner third wire portion 123 of the resistive wire 120 will dominate the measured resistance, with smaller resistance contributions from the wider (W₁) first and second wire portions 121 and 122.

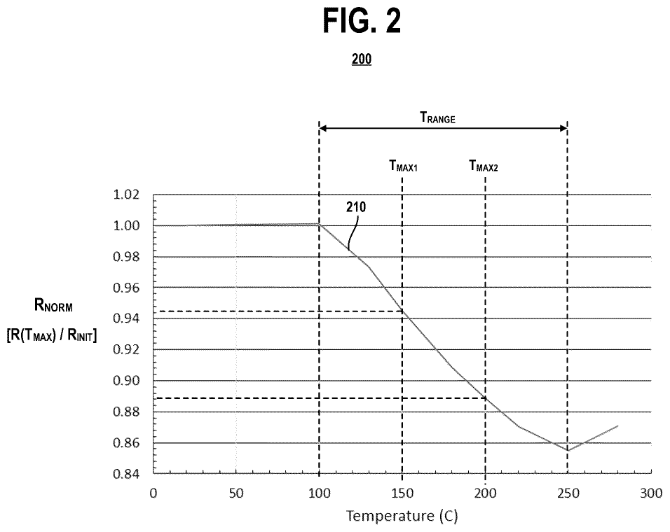

After heating the resistance temperature sensor 110 to a certain temperature, the electrical resistance (conversely, conductance) of the stack of thin-film metal layers L₁, L₂, L₃, L₄, L₅, and L₆ will be permanently changed as a result of adjacent layers of the stack of thin-film metal layers L₁, L₂, L₃, L₄, L₅, and L₆ becoming alloyed or mixed due to the heating. For a given amount of metal layers, heating the resistance temperature sensor 110 to a target maximum temperature (T_{MAX}) causes the adjacent thin-film metal layers to intermix, which changes the interfaces in a way that progresses with temperature over a certain working temperature range. In an exemplary embodiment, as explained in further detail below in conjunction with FIG. 2, the resistance temperature sensor 110 comprises a negative temperature coefficient, wherein the electrical resistance decreases as temperature increases in a known and repeatable manner. In some embodiments, as explained in further detail below, heating may be localized to the third (middle) wire portion 123 of the resistive wire 120. The first and second wire portions 121 and 122 can be made wider or shorter to reduce the sensitivity of the first and second wire portions 121 and 122 to the localized heating, if the desire is to find only the temperature reached by the third wire portion 123 of the resistance temperature sensor 110.

It is to be noted that the exemplary device structure shown in FIGS. 1A and 1B can be fabricated using known semiconductor fabrication techniques. For example, an initial stage of fabrication comprises forming the first electrode 101 and the second electrode 102 on the surface of the substrate 100. For example, in some embodiments, the first and second electrodes 101 and 102 are formed by depositing a layer of metal material, and photolithographically patterning the layer of metal material to form the first and second electrodes 101 and 102. In some embodiments, the first and second electrodes 101 and 102 are formed of a metal such niobium having a desired thickness (e.g., 200 nm). The first and second electrodes 101 and 102 are preferably formed of the same or similar superconducting metal material that is utilized to form capacitor pads of superconducting qubits.

After forming the first and second electrodes 101 and 102, the resistance temperature sensor 110 is fabricated using a process which comprises depositing multiple thin-film layers of metal material (e.g., layers of T₁ and Pt) onto the surface of the substrate 100 using a resist mask and a liftoff process to form the shapes of the various portions of the resistance temperature sensor 110 (e.g., the first and second contact pads 111 and 112, and the resistive wire 120). More specifically, in an exemplary fabrication process, the substrate 100 with the patterned first and second electrodes 101 and 102 is coated with a photoresist layer (e.g., a poly methyl methacrylate (PMMA) resist), and the photoresist layer is patterned by performing electron beam lithography using standard techniques. The patterning of the photoresist layer results in the formation of a photoresist mask which comprises a footprint image of the resistance temperature sensor 110, wherein the footprint image of the photoresist mask is aligned to the first and second electrodes 101 and 102 such that the images of the first and second contact pads 111 and 112 are aligned over the edges of the first and second electrodes 101 and 102.

After forming the photoresist mask, the stack of thin-film metal layers L₁, L₂, L₃, L₄, L₅, and L₆ are sequentially deposited using, e.g., a double angle electron beam evaporation through the photoresist mask with the substrate 100 tilted to ensure good coverage on sidewalls/edges of the first and second electrodes 101 and 102. For example, in an exemplary embodiment, the substrate 100 is tilted 45 degrees in a first direction so that the evaporation source faces toward the sidewall of the first electrode 101. The first thin-film metal layer L₁ is then formed by depositing a 5 nm thick layer of T₁ at the 45 degrees angle toward the sidewall of the first electrode 101 in the first direction to cover exposed surfaces of the substrate 100 and the first and second electrodes 101 and 102, and the second thin-film metal layer L₂ is formed over the first thin-film metal layer L₁ by depositing a 30 nm thick layer of Pt in the first direction. The substrate 100 is then tilted to 45 degrees in a second direction (opposite the first direction) so that the evaporation source faces toward the sidewall of the second electrode 102. The third thin-film metal layer L₃ is then formed over the second thin-film metal layer L₂ by depositing a 5 nm thick layer of T₁ at the 45 degrees angle toward the sidewall of the second electrode 102 in the second direction, the fourth thin-film metal layer La is formed over the third thin-film metal layer L₃ by depositing a 30 nm thick layer of Pt in the second direction, the fifth thin-film metal layer L₅ is formed over the fourth thin-film metal layer La by depositing a 5 nm thick layer of T₁ in the second direction, and the sixth thin-film metal layer Le is formed over the fifth thin-film metal layer L₅ by depositing a 30 nm thick layer of Pt in the second direction. The overburden metal material and photoresist mask are then removed using suitable techniques, which results in the exemplary structure as shown in FIGS. 1A and 1B.

The first and second electrodes 101 and 102 are utilized as contact landing pads for electrical probes to perform resistance measurements of the resistance temperature sensor 110, using probing techniques as discussed in further detail below. The first and second contact pads 111 and 112 of the resistance temperature sensor 110 are configured to make sufficient low-resistance electrical contact of the resistance temperature sensor 110 to the first and second electrodes 101 and 102. The first and second wire portions 121 and 122 essentially serve as leads that connect the third (thinner) wire portion 123 to the first and second contact pads 111 and 112.

It is to be noted that the exemplary stack of thin-film metal layers L₁, L₂, L₃, L₄, L₅, and L₆ shown in FIG. 1B is merely an exemplary, non-limiting embodiment of a stack structure for implementing the resistance temperature sensor 110, and that other metal materials and/or number of layers can be used to implement a resistance temperature sensor. For example, while the exemplary stack of thin-film metal layers L₁, L₂, L₃, L₄, L₅, and L₆ shown in FIG. 1B comprises three (3) repeating layers of Ti/Pt layer pairs, the resistance temperature sensor 110 can be implemented with one more additional Ti/Pt layer pairs. The overall initial resistance of the resistance temperature sensor 110 will (i) decrease as the metal layers are made thicker, and (ii) increase as the metal layers are made thinner.

In addition, the dynamic range of temperature sensing of a given resistance temperature sensor will vary based on, e.g., the number of thin-film metal layers (or number of layer pairs) and/or the thicknesses of such thin-film metal layers. Indeed, depending on the number of thin-film metal layers (or number of layer pairs) and/or the thicknesses of such thin-film metal layers, resistance temperature sensors will have different responses (with respect to change of resistance as a function of temperature), resulting in changing the relative and absolute resistance changes obtained upon heating. Given that changes in resistance of a given resistance temperature sensor are due to intermixing or alloy formation between thin-film metal layers, there are various factors that impact the dynamic range of temperature sensing of a given resistance temperature sensor. Such factors include, but are not limited to, (i) the resistance difference between the initial resistance of the stack of thin-film metal layers as initially formed, and the resistance of the stack of thin-film metal layers after heating to a given temperature (ii) the temperature range over which resistance changes occur; and (iii) the thermodynamics and kinetics of the changes. In this regard, some material stacks may provide a sharp change to a new state, which is useful for detecting a transition above a narrow range of temperatures, while some material stacks may provide a gradual change to a new state, which is useful for detecting a transition above a wider range of temperatures.

FIG. 2 is a graph which illustrates resistance as a function of temperature of a resistance temperature sensor, according to an exemplary embodiment of the disclosure. In particular, FIG. 2 is a graph 200 which plots a normalized resistance RNORM (Y-axis) as a function of temperature in degrees Celsius (X-axis), where

$${R}_{NORM} = \frac{{R}_{TMAX}}{{R}_{INT}} ,$$

where R_{INT} denotes a measured initial resistance of a given temperature sensor after fabrication, and R_{TMAX} denotes a measured resistance of the given temperature sensor after the given temperature sensor is heated to a given maximum temperature T_{MAX} for a given duration.

Moreover, FIG. 2 depicts a curve 210 (or calibration curve 210) which shows normalized resistance as a function of temperature, for a given a resistance temperature sensor having a multilayer metal structure, such as shown in FIGS. 1A and 1B. The curve 210 shows that the resistance temperature sensor has an initial resistance R_{INIT} (as fabricated) which remains relatively constant when the resistance temperature sensor is heated to a maximum temperature T_{MAX} that falls within a range of 0° C. to about 100° C. On the other hand, the curve 210 shows that the resistance of the temperature sensor decreases to an amount which correspond to

$${R}_{NORM} = \frac{{R}_{{TMAX}_{1}}}{{R}_{INT}} ≅ 0.945 ,$$

when the resistance temperature sensor is heated to a maximum temperature T_{MAX1}=150° C. In addition, the curve 210 shows that the resistance of the temperature sensor decreases to an amount which corresponds to a

$${R}_{NORM} = \frac{{R}_{{TMAX}_{2}}}{{R}_{INT}} ≅ 0.89 ,$$

when the resistance temperature sensor is heated to a maximum temperature T_{MAX2}=250° C.

Furthermore, it is to be noted that a resistance change of the given resistance temperature sensor is persistent after the temperature sensor is heated to a certain maximum temperature T_{MAX}. For example, based on the exemplary curve 210 shown in FIG. 2, assume that the given resistance temperature sensor is heated to the maximum temperature T_{MAX1}=150° C., and then cooled down to room temperature. The resistance temperature sensor will have a resistance of R_{TMAX1} when measured at room temperature. Assume further that the given resistance temperature sensor is reheated to a maximum temperature T_{MAX1}=150° C. (or less), and then cooled down to room temperature. The resistance temperature sensor will have the same resistance of R_{TMAX1} when remeasured at room temperature. On the other hand, assume that the given resistance temperature sensor is reheated the maximum temperature T_{MAX2}=250° C., and then cooled down to room temperature. The resistance temperature sensor will have a resistance of R_{TMAX2} when remeasured at room temperature, as a result of being reheated to the maximum temperature of T_{MAX2}. Therefore, when the resistance temperature sensor is heated to different maximum temperatures at different times, the resistance temperature sensor will have a resistance which indicates the highest maximum temperature to which the resistance temperature sensor was heated.

Moreover, the microfabrication of a plurality of resistance temperature sensors having nominally identical multilayer metal structures, such as shown in FIGS. 1A and 1B, results in a set of resistance temperature sensors having the same or similar resistance/temperature characteristics. For example, assuming a plurality of resistance temperature sensors are formed on a given substrate (e.g. silicon substrate), or a plurality of resistance temperature sensors are formed on each of a plurality of different substrates using the same fabrication process, the plurality of resistance temperatures formed on the same substrate and across different substrates will have substantially the same resistance/temperature profiles, e.g., similar calibration curves such as shown in FIG. 2, wherein Δ_{NORM} is reproduceable with a difference of less than 0.01. In other words, the resistance/temperature curves of a plurality of resistance temperature sensors, which have nominally identical architectures that are formed on substrates with the same substrate material (e.g., silicon), will be substantially the same, thereby resulting in the plurality of resistance temperature sensors having a repeatable response with regard to resistance change as a function of temperature.

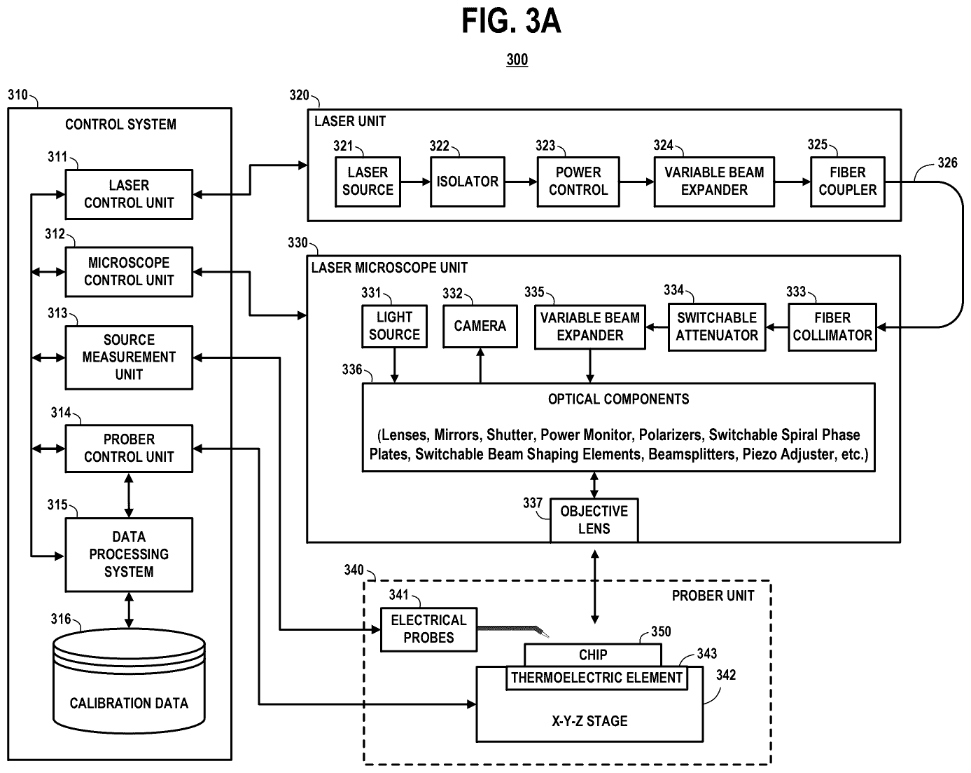

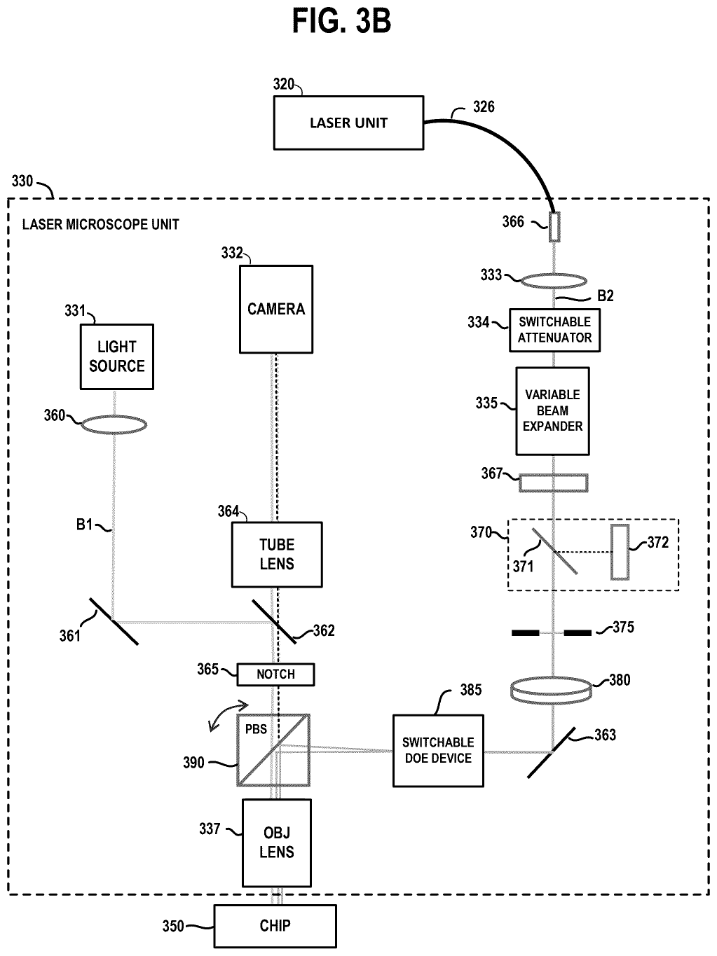

FIGS. 3A and 3B schematically illustrate a thermal annealing system, according to an exemplary embodiment of the disclosure. In particular, FIGS. 3A and 3B schematically illustrate an exemplary laser annealing system 300 which can be utilized to perform various thermal annealing calibration processes as discussed herein to generate calibration data (e.g., resistance/temperature profiles) for resistance temperature sensors, and to utilize calibrated resistance temperature sensor to perform laser annealing calibration processes to generate calibration data to support localized thermal annealing of Josephson junctions using structured laser beam illumination patterns. In addition, the laser annealing system 300 is configured to implement LASIQ (Laser Annealing of Stochastically Impaired Qubits) tuning methods for laser annealing Josephson junctions of qubits, post-fabrication, to adjust and stabilize the junction resistances Rn and thereby selectively tune the individual qubit frequencies via laser thermal annealing of the respective Josephson junctions.

As schematically shown in FIG. 3A, the laser annealing system 300 comprises a control system 310, a laser unit 320, an optical fiber 326, a laser microscope unit 330, and a prober unit 340. The control system 310 comprises a laser control unit 311, a microscope control unit 312, a source measurement unit (SMU) 313, a prober control unit 314, a data processing system 315, and a database of calibration data 316. In some embodiments, the laser unit 320 comprises a laser source 321, an isolator 322, a laser power control block 323, a variable beam expander 324, and a fiber coupler 325. In some embodiments, the laser microscope unit 330 comprises a light source 331, a camera 332, a fiber collimator 333, a switchable attenuator device 334, a variable beam expander 335, a plurality of optical components 336, and an objective lens 337. The plurality of optical components 336 comprise various types of optical components and elements including, but not limited to, lenses, mirrors, an electronic shutter, a power monitor, polarizers, variable spiral phase plates (or vortex plates), variable beam shaping elements (e.g., different diffractive optical elements), beam splitters, and piezoelectric actuators, etc. An exemplary architecture of the laser microscope unit 330 will be discussed in further detail below in conjunction with FIG. 3B.

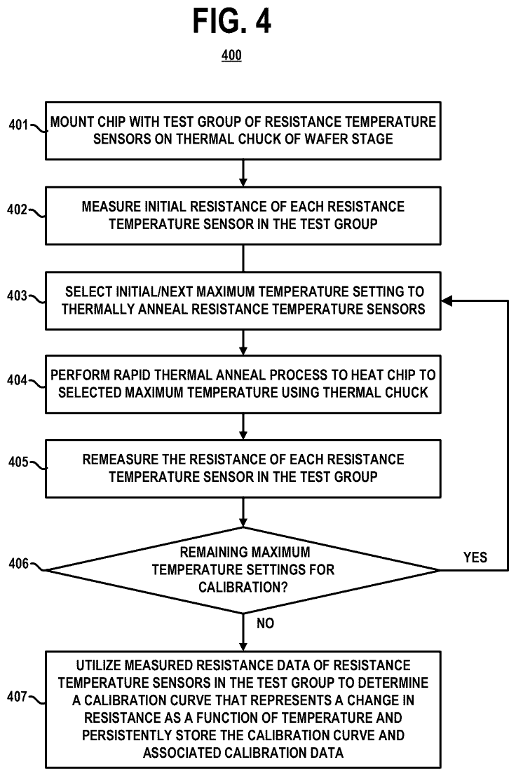

The prober unit 340 comprises electrical probes 341 and an X-Y-Z stage 342 (or wafer stage 342), wherein the wafer stage 342 comprises a thermoelectric element 343 (alternatively, thermal chuck 343). A test chip 350 (or any other similar device under test) can be mounted on the X-Y-Z stage 342. In some embodiments, the test chip 350 comprises a plurality of resistance temperature sensors that are thermally annealed using the thermal chuck 343 to implement an exemplary calibration process, as will be discussed below in conjunction with FIG. 4. In other embodiments, the test chip 350 comprises a plurality of test structures having resistance temperature sensors, which are constructed to emulate the geometric structures of various quantum devices, wherein the test structures are laser annealed using various structured laser beam illumination patterns and laser power to determine accurate thermal profiles of such structured laser beam illumination patterns for use in laser annealing corresponding quantum devices that are emulated by the test structures.

The X-Y-Z stage 342 of the prober unit 340 is controllably moved in three dimensions (under control of the prober control unit 314) during, e.g., thermal annealing calibration operations to align target test structures of the test chip 350 within the field of view (FOV) of the laser microscope unit 330. The alignment allows the electrical probes 341 (e.g., a set of microscopic contacts or probes of the probe card) to be aligned with contact pads on the surface of the test chip 350 to thereby enable contact between the electrical probes 341 and contact pads/electrode of test structures on the test chip 350 to perform resistance measurements for measuring the resistance of resistance temperature sensors by operation of the SMU 313.

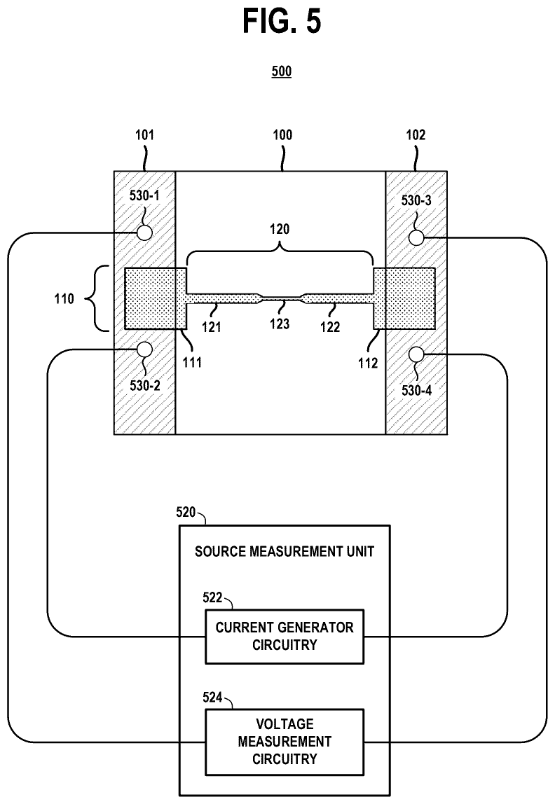

For example, in some embodiments, the SMU 313 operates in conjunction with the prober control unit 314 and the prober unit 340 to perform a 4-wire resistance measurement (or Kelvin resistance measurement) to measure the resistance of a given resistance temperature sensor. In general, a 4-wire (Kelvin) resistance measurement involves determining the resistance of a given resistance temperate sensor by driving a current (I) flow through the resistance temperature sensor, while concurrently measuring a voltage (V) drop across the resistance temperature senor, and determining the junction resistance R_{J} from Ohm's Law, i.e., R_{J}=V/I. The SMU 313 comprises a test instrument which combines a sourcing function (to precisely source voltage and/or current pulses/signals) and a measurement function (measure voltage and/or current) on a group of electrical probes 341. An exemplary method for performing 4-wire (Kelvin) resistance measurement operation will be discussed in further detail below in conjunction with FIG. 5. In general, a 4-wire (Kelvin) resistance measurement involves determining the resistance of a given Josephson junction by measuring a current (I) flow through the junction as well as a voltage (V) drop across the junction, and determining the junction resistance R_{J} from Ohm's Law, i.e., R_{J}=V/I.

Moreover, in some embodiments, the prober control unit 314 utilizes pattern recognition techniques to automatically align the electrical probes 341 with contact pads on the surface of the test chip 350. More specifically, in some embodiments, the prober control unit 314 operates in conjunction with the microscope control unit 312 to utilize the laser microscope unit 330 as pattern recognition optics to identify the positions of contact pads on the surface of the test chip 350 relative to the tips of the electrical probes 341. The alignment ensures precise registration between the contact pads of test structures and the tips of the electrical probes 341. To facilitate the alignment, an automated pattern recognition process is performed in which features of an image captured by the camera 332 are automatically aligned to corresponding features of a given template image to ensure proper positioning of target contact pads/electrodes of test structures and, thereby, ensure accurate registration between the contact pads and the electrical probes 341 to perform resistance measurements, as well as align a given test structure in the FOV of the laser microscope unit 330 for laser annealing operations.

In some embodiments, the thermoelectric element 343 (or thermal chuck) is utilized as a thermal control system (e.g., temperature-controlled wafer chuck system, or other suitable types of heating/cooling systems) that is configured to (i) heat the test chip 350 to perform a rapid thermal anneal process to heat a group of temperature sensors on a given test chip to perform certain operations (e.g., perform resistance measurements) as discussed below. In some embodiments, the temperature-controlled wafer chuck system can be temperature controlled (via the thermoelectric element 343) in a range of −60° C. to 300° C.

In some embodiments, the laser unit 320 and the laser microscope unit 330 comprise modular units that are coupled together via the optical fiber 326. In some embodiments, the optical fiber 326 comprises a single-mode (SM) polarization-maintaining (PM) optical fiber, which is configured to preserve a linear polarization of linearly polarized light that is injected into the optical fiber 326 by the laser unit 320 and propagated to the laser microscope unit 330. The laser microscope unit 330 can be integrated onto the prober unit 340 (e.g., a wafer-scale prober). In this regard, in some embodiments, the laser unit 320, the laser microscope unit 330, and the prober unit 340 can be physically coupled/attached to each other to form an integrated laser annealing apparatus which is configured to perform, e.g., laser anneal operations to calibrate structured laser beam illumination patterns for laser annealing, as well as performing resistance measurements, under the control of the control system 310. In some embodiments, the control system 310 is operatively/communicatively coupled to the laser unit 320, the laser microscope unit 330, and the prober unit 340 via wires and/or wirelessly. The control system 310 comprises hardware and/or software for automated control of various operations of the laser unit 320, the laser microscope unit 330, and the prober unit 340 of the laser annealing system 300.

The laser unit 320 is configured to generate a laser beam that is transmitted to the laser microscope unit 330 via the optical fiber 326, wherein the laser microscope unit 330 is configured to generate a wide variety of structured laser beam illumination patterns for laser annealing superconducting quantum devices having variable Josephson junction geometries. In some embodiments, the laser source 321 comprises a solid-state diode pump to generate laser energy, and a laser head to generate a focused laser beam from the laser energy emitted from the solid-state diode pump. In some embodiments, the diode pump comprises a 532 nanometer (nm) (frequency doubled) diode-pumped solid-state laser (e.g., a second harmonic generation (SHG) laser). In some embodiments, the power level of the laser source 321 (e.g., solid-state diode pump) can be adjusted by the control system 310. For example, the power level of the laser source 321 can be set to one of a plurality of different power level settings (e.g., lower power, medium power, high power settings). The isolator 322 is configured to provide polarization cleanup and to provide optical isolation to mitigate unwanted feedback to the laser head of the laser source 321.

The laser power control block 323 is configured to actively monitor, control, and calibrate the power level of a laser beam generated by the laser source 321. In some embodiments, the laser power control block 323 generates an electrical signal that is indicative of the laser power level, and the electrical signal is feedback to the laser control unit 311 of the control system 310, which generates control signals that are applied to the laser power control block 323 to adjustably control a laser power level for performing laser annealing operations. More specifically, in some embodiments, the power level of the laser beam can be coarsely adjusted by controlling the power output of the laser source 321, while the power level of the laser beam can be finely adjusted by operation of the laser power control block 323. The variable beam expander 324 is configured to adjust a diameter of the laser beam that is input to the fiber coupler 325 to adjust a focus (e.g., focal point) of a laser beam by the fiber coupler 325 to optimize a coupling of the laser beam into the optical fiber 326.

In the laser microscope unit 330, the fiber collimator 333 (e.g., collimating lens) is configured to transform the laser light which is output from the optical fiber 326 into a free-space collimated laser beam. In some embodiments, the laser microscope unit 330 comprises a power monitor which comprises, e.g., a beam sampler (e.g., beam splitter) and photodiode, to monitor the power of the collimated laser beam to enable precise exposure control downstream from the power control/adjustment mechanisms provided by the laser unit 320.

The switchable attenuator device 334 comprises a plurality of attenuation elements. The switchable attenuator device 334 is configured to selectively position a given attenuation element in an optical path of the collimated laser beam generated by the fiber collimator 333 to adjust a laser illumination intensity of the collimated laser beam based on the given attenuation element. The attenuation elements are configured to have different optical densities for achieving different attenuation levels of the laser beam illumination intensity.

The variable beam expander 335 is configured to adjust a diameter of the collimated laser beam. As explained in further detail below the variable beam expander 355 is configured to adjust the beam diameter of the collimated laser beam, which results in adjusting the diameters of the image plane focused laser spots that are incident on a surface of the test chip 350 to laser anneal Josephson junctions of superconducting quantum devices formed on the surface of the test chip 350.

The plurality of optical components 336 of the laser microscope unit 330 include an electronic shutter that is operated under control of, e.g., the microscope control unit 312 of the control system 310, to control the time duration of laser exposure when performing a laser annealing operation. For example, the electronic shutter can be opened for a given duration of time when annealing a target device to allow annealing laser beams to be projected onto the test chip 350, and then automatically close after the given duration of time. In this regard, the laser power level and the pulse duration (laser exposure) can be controlled to achieve a desired results (e.g., change in the resistance of a laser annealed Josephson junction).

The additional optical components 536 of the laser microscope unit 330 further include switchable laser beam shaping elements (e.g., diffractive optical elements (DOEs)) having various diffraction gratings that are configured to split a single laser beam into two or more laser beams with slightly different angles relative to one another. The diffractive optical elements include, for example, diffractive beam splitters that are configured to split a single laser beam into several beams (diffraction orders) in a predefined configuration (e.g., dual laser spots, three laser spots, a quad-spot pattern, etc.). A diffractive beam splitter comprises a holographic optical element that imparts a precise angle (e.g., a 0.5 degree shift) to an incoming laser beam in plus and minus angular directions relative to a reference plane, to thereby generate a plurality of outgoing laser beams. In some embodiments, the switchable DOE components include one or more 2-by-2 diffractive beam splitters, which are configured to split a single collimated laser beam into four separate laser beams, which results in a final quad-spot illumination pattern that is projected onto the surface of the test chip 350 at a target location, exemplary embodiments of which will be discussed in further detail below. The switchable DOE components comprise a variety of diffractive beam splitters that can be selected for use to generate any desired number (e.g., 2, 3, 5, 6, etc.) of laser beams with defined illumination patterns tailored to different applications.

The laser microscope unit 330 implements the light source 331 and the camera 332 for illuminating and viewing target features on the surface of the test chip 350 within a given field of view (FOV) of the laser microscope unit 330. In some embodiments, the light source 331 comprises any suitable light generating device including one or more light emitting diodes (LEDs) with desired photonic wavelengths, a monochromatic light source, etc. The light source 331 together with some of the plurality of optical components 336 in the optical viewing path implement Kohler illumination to create uniform illumination of the target features in the FOV of the laser microscope unit 330 and to ensure that an image of the light source 331 is not visible in the resulting images captured by the camera 332.

In some embodiments, the camera 332 comprises a charge-coupled device (CCD) image sensor, or an infrared (IR) complementary metal oxide semiconductor (CMOS) image sensor. The camera 332 is utilized to capture images of a target region on the surface of the test chip 350 to facilitate alignment to the target structure in the FOV when performing resistance measurements and laser annealing operations as discussed herein. As noted above, in some embodiments, a target structure is aligned to the center of the FOV of the laser microscope unit 330 using pattern recognition, e.g., a corresponding template image. Also, in some embodiments, more than one camera may be used in parallel, by splitting the image path using a beam splitter and using, for example, an IR CMOS camera in addition to a visible wavelength camera, which may be used for process monitoring (e.g., a wide FOV for inspection, process tracking, or the like).

The objective lens 337 is the lens that is located closest to the device under test (e.g., test chip 350) and serves to provide the base magnification for generating a magnified image that is viewed by the camera 332, and to project a laser beam illumination pattern (e.g., quad-spot pattern) onto the surface of the test chip 350. In some embodiments, the objective lens 337 comprises a long working distance (WD) objective lens. In an exemplary non-limiting embodiment, the objective lens 337 (together with an optional second objective lens) is configured to condense laser beams (on order of mm) to laser spots (on order of microns) by 4×, while providing 20× image magnification.

FIG. 3B schematically illustrates an exemplary architecture of the laser microscope unit 330 of the laser annealing system 300. In particular, FIG. 3B schematically illustrates an exemplary embodiment of the laser annealing system 300 showing the laser unit 320 optically coupled to the laser microscope unit 330 via the optical fiber 326. In some embodiments, as noted above, the laser microscope unit 330 comprises an integrated optical system with various optical components to enable laser annealing operations and to enable optical visualization and characterization operations to precisely control and visualize laser illumination geometry and alignment for laser annealing operations. In particular, the laser microscope unit 330 comprises various components that are disposed in optical paths to enable optical visualization and characterization operations, wherein such components include, e.g., the light source 331, the camera 332, a lens 360, a tube lens 364, a mirror 361, a beam splitter 362, a notch filter 365, a polarizing beam splitter 390 (with X-Y-Z piezoelectric actuator control), and the objective lens 337. The light source 331 and the camera 332 are configured for illuminating and viewing target features on the surface of the test chip 350 within a given FOV of the laser microscope unit 330. As noted above, the light source 331 comprises any suitable light generating device including one or more LED elements with desired photonic wavelengths, a monochromatic light source, etc. The camera 332 may comprise a CCD image sensor, or an IR CMOS image sensor, etc.

The light source 331, the lens 360, the mirror 361, and the beam splitter 362, are configured to implement Kohler illumination in the optical viewing path to create uniform illumination of the target features in the FOV of the laser microscope unit 330 and to ensure that an image of the light source 331 is not visible in the resulting images captured by the camera 332. In a light source path, the lens 360 is configured to “parallelize” the light emitted from the light source 331 to form an illumination beam B1. The illumination beam B1 is directed along an optical path by the mirror 361 to the beam splitter 362, through the notch filter 365, the polarizing beam splitter 390, and focused by the objective lens 337 to illuminate the portion of the test chip 350 within the FOV of the objective lens 337. The tube lens 364 comprises a multi-element optical component that is configured to focus parallel light coming through the objective lens 337 onto the image plane of a focal plane array of the camera 332. The notch filter 365 is configured to attenuate the light intensity at or near the wavelength (e.g., 532 nm) of the laser beam illumination using, e.g., engineered dielectric coatings or otherwise. In an exemplary embodiment, the notch filter 365 is selected to filter light at and near 532 nm, to prevent scattered and reflected light from the sample from saturating the camera 332, and thereby enable simultaneous laser annealing and optical imaging.

Furthermore, the laser microscope unit 330 comprises various components that are disposed in a laser beam path to perform various operations to enable laser annealing. For example, in the laser beam path, the laser microscope unit 330 comprises an optical fiber output interface element 366 (e.g., fiber optic ferrule), the fiber collimator 333, the switchable attenuator device 334, the variable beam expander 335, a clean-up polarizer 367, a power monitor 370 (which comprises a beam sampler 371 and a photodiode 372), an electronic shutter 375, a spiral phase plate device 380, a mirror 363, and a switchable DOE device 385. In addition, the laser beam path comprises the polarizing beam splitter 390, and the objective lens 337.

In the laser beam path, the optical fiber output interface element 366 is aligned to the fiber collimator 333. The fiber collimator 333 is configured to collimate the laser light emitted from the end of the optical fiber 326 to generate a collimated laser beam B2. The switchable attenuator device 334 comprises a plurality of attenuation elements which can be selectively placed in the laser beam path of the collimated laser beam B2 to achieve a desired attenuation of the laser beam power (e.g., discrete attenuation levels in a range of 0% attenuation to 90% attenuation). The switchable attenuator device 334 enables rapid control of laser annealing power for different thermal annealing profiles and operating conditions. The variable beam expander 335 is configured to controllably adjust (e.g., increase or decrease) the diameter of the collimated laser beam B2. The variable beam expander 335 is utilized to control a laser beam spot size (e.g., spot diameter) for various laser beam illumination patterns which comprise one or more laser beam spots.

The clean-up polarizer 367 is configured to remove stray polarization modes (e.g. propagating in cladding modes) in advance of laser power measurements enabled by the power monitor 370, to thereby significantly increase the accuracy of laser power measurement. The power monitor 370 operates by utilizing the beam sampler 371 to direct some laser energy to the photodiode 372, and the photodiode 372 generates an electrical signal that is measured (via the microscope control unit 312) to determine the laser power level. The electronic shutter 375 is operated (via the microscope control unit 312) for precise control of laser beam exposure for laser annealing a given device. In other words, the electronic shutter 375 enables precise control of an annal time for performing a given laser anneal operation. In some embodiments, the electronic shutter 375 may be used in conjunction with an electronic shutter of the laser unit 320, to minimize the impact of any vibrations induced from the shutter motion on the optical illumination. For example, a shutter in the laser unit 320 may initially be closed while the electronic shutter 375 is initially open, immediately prior to an anneal operation. When the anneal operation is to be commenced, the shutter of the laser unit 320 may open, and the laser spot pattern is exposed upon the target device. By first opening the electronic shutter 375 of the laser microscope unit 330 before commencing a laser anneal operation, any vibrations incurred by opening the shutter of the laser unit 320 will be isolated to the laser unit 320 and will not impact the stability of the beam exiting the objective lens 337 of the laser microscope unit 330. Once the anneal operation is complete (i.e., some desired annealing time has elapsed), the anneal operation may be stopped by closing the electronic shutter 375 of the laser microscope unit 330. Here, with the shutter close operation, any mechanical vibrations caused by the electronic shutter 375 operation no longer impact the anneal operation, as the illumination has been blocked by closure of the electronic shutter 375. Thus, by utilizing the two shutters in the correct order, it is possible to eliminate the impact of mechanical vibrations on the optical beam stability.

The spiral (vortex) phase plate device 380 is configured to convert a laser beam spot (e.g., Gaussian laser spot) into a laser beam with a vortex shape (e.g., annulus) which comprises a donut shape. As explained in further detail below, the spiral phase plate device 380 is utilized in instances where a laser beam illumination pattern having one or more annulus-shaped laser beam spots is desired for laser annealing a given superconducting quantum device. On the other hand, the spiral phase plate device 380 is not utilized in instances where a laser beam illumination pattern having one or more Gaussian-shaped laser spots is desired for laser annealing a given superconducting quantum device. In some embodiments, the spiral phase plate device 380 is configured to adjust the shape of the annulus laser spot.

The mirror 363 is configured to direct a laser beam along an optical path to the switchable DOE device 385. The switchable DOE device 385 comprises a plurality of laser beam shaping diffractive optical elements which can be selected to generate various types of laser beam illumination patterns (multi-spot patterns) having two or more Gaussian-shaped laser beam spots or two or more annulus-shaped laser beam spots, the details of which will be explained below. The switchable DOE device 385 comprises a variety of DOE components disposed on a rotatory stage, or a linear stage, which can be operated to place a given DOE element in the path of the laser beam to generate a target multi-spot laser beam illumination pattern to provide a desired thermal profile for laser annealing a given superconducting quantum device.

In some embodiments, the polarizing beam splitter 390 is mounted on an automated piezoelectric actuator stage to provide rapid precision alignment of a laser beam illumination pattern to a center of the FOV of the objective lens 337. In some embodiments, the piezoelectric actuator stage comprises X-Y-Z actuators to fine tune the alignment between a laser beam illumination pattern and target device in the FOV of the objective lens 337 in conjunction with an image pattern recognition process performed via pattern recognition of the target device. In some embodiments, the pattern recognition process may be performed by comparing the sample image with a template image using a cross-correlation to determine the specific type of device being annealed. However, in general, any other method which quantifies the similarity of a target image on the FOV to a template image, with the purpose of finding the best possible match amongst a series of template images, may be used.

As noted above, exemplary embodiments of the disclosure include resistance temperature sensor calibration processes that are implemented to acquire calibration data which is utilized to generate calibration curves that represent resistance/temperature profiles for resistance temperature sensors, such as shown in FIG. 2. For example, FIG. 4 illustrates a flow diagram of a method for performing a resistance temperature sensor calibration process, according to an exemplary embodiment of the disclosure. More specifically, FIG. 4 illustrates a resistance temperature sensor calibration process 400 (or calibration process 400) which, in some embodiments, can be implemented using the laser annealing system 300 of FIGS. 3A and 3B. For example, an initial step of the calibration process 400 comprises mounting a test chip on the thermal chuck 343 of the wafer stage 342, wherein the test chip comprises a test group of resistance temperature sensors that are formed on a substrate (block 401). In some embodiments, the test group of resistance temperature sensors are constructed to emulate the size, placement, geometry, etc., of devices that are to be thermally annealed. For example, in some embodiments, the test group of resistance temperature sensors are constructed to emulate the size, placement, geometry, etc., of Josephson junctions of quantum device such as qubits, which are formed on a semiconductor substrate (e.g., silicon substrate). For example, the test group of resistance temperature sensors can include multiple instances (e.g., 5 or more) of the exemplary resistance temperature sensor 110 shown in FIGS. 1A and 1B, wherein each resistance temperature sensor in the test group comprises a nominally identical structure.

The calibration process proceeds by measuring the initial resistance River of each resistance temperature sensor in the test group (block 402). In some embodiments, the resistance of the resistance temperature sensors is measured using the prober unit 340 and SMU 313 to perform a 4-wire (Kelvin) resistance measurement to measure the initial resistance R_{INIT} of each resistance temperature sensor in the test group. In some embodiments, the initial resistance R_{INIT} of each resistance temperature sensor in the test group is measured at a target temperature, e.g., 0° C., wherein the test chip is actively cooled to the target temperature via the thermal chuck to perform the resistance measurements. An exemplary process for performing a 4-wire (Kelvin) resistance measurement will be discussed in further detail below in conjunction with FIG. 5.

Next, a set of trial thermal annealing operations are performed on the test group of resistance temperature sensor by using the thermal chuck 343 of the wafer stage 342 to heat the test chip to a plurality of different (increasing) maximum temperature settings, T_{MAX1}, T_{MAX2}, . . . , T_{MAXn}, and measuring the resistances of the temperature sensors after thermally annealing at each maximum temperature setting. For example, the maximum temperature settings, T_{MAX1}, T_{MAX2}, . . . , T_{MAXn} can include a set (n=10) of maximum temperature settings that begin at T_{MAX1}=25° C., and increase at increments of 25° C. up to T_{MAX10}=250° C. The thermal annealing operations begin by selecting the initial maximum temperature setting T_{MAX1} (block 403), and performing a rapid thermal anneal process to heat the test chip to the selected maximum temperature setting using the thermal chuck (block 404). For example, in some embodiments, the rapid thermal anneal process is performed by using the thermal chuck to rapidly heat the test chip to the selected maximum temperature setting in a short duration (e.g., order of minutes), and then allowing the test chip to cool down to target temperature for performing resistance measurements. For example, in some embodiments, the thermal chuck can be unitized to actively cool the test chip to a target temperature, e.g., 0° C. to perform resistance measurements.

When the test chip is cooled down to the target temperature for resistance measurements, the calibration process proceeds to remeasure the resistance of each resistance temperature sensor in the test group and record the measured resistance values (block 405). As noted above, in some embodiments, the resistances of the temperature sensors are measured using the prober unit 340 and SMU 313 to perform a 4-wire (Kelvin) resistance measurement to measure the resistance of each resistance temperature sensor in the test group, as discussed in further detail below in conjunction with FIG. 5.

The thermal annealing and resistance measurement operations (block 404 and 405) are repeated for each remaining maximum temperature setting. For example, if there are one or more remaining maximum temperature settings for calibration (affirmative determination in block 406), the calibration process proceeds to select the next maximum temperature setting to thermally anneal the test group of resistance temperature sensors on the test chip (return to block 403), and the thermal annealing and resistance measurement operations are performed again (block 404 and 405) for the selected maximum temperature setting.

On the other hand, if there are no remaining maximum temperature settings for calibration (negative determination in block 406), the calibration process proceeds to utilize the measured resistance data (calibration data) of the test group of resistance temperature sensors to determine a calibration curve which represents the resistance as a function of temperature of the temperature sensors, and persistently store the calibration curve and associated calibration data in, e.g., the database of calibration data 316, FIG. 3A (block 407). For example, in some embodiments, the calibration curve is determined by computing a plurality of data points, where each data point represents an average of the measured resistances of the test group of resistance temperature sensors initially and after thermal annealing at a given maximum temperature setting, and utilizing statistical methods and curve fitting techniques to fit the data points to a calibration curve which represents resistance as a function of temperature for the resistance temperature sensors. In particular, an initial data point can be computed as an average of the measured initial resistances River of the resistance temperature sensors in the test group, and other data points can be computed for each maximum temperature setting T_{MAX1}, T_{MAX2}, . . . , T_{MAXn}, where a given data point for a given maximum temperature setting is computed as an average of the measured resistances of the resistance temperature sensors in the test group after being thermally annealed at the given maximum temperature setting. In some embodiments, the calibration curve for the test group of resistance temperature sensors can be determined using a curve fitting process to fit the data points (representing average resistance values) to a curve using a polynomial curve fitting process (e.g., a second order (or higher order) polynomial curve fitting process). The curve fitting process results in a calibration curve, an exemplary embodiment of which is shown and discussed above in conjunction with FIG. 2.

FIG. 5 schematically illustrates a method for measuring a resistance of a resistance temperature sensor, according to an exemplary embodiment of the disclosure. In particular, FIG. 5 schematically illustrates a method 500 for utilizing a 4-probe configuration to perform a 4-wire resistance measurement (or Kelvin resistance measurement) to measure the resistance of a resistance temperature sensor. In some embodiments, FIG. 5 schematically illustrates an exemplary embodiment and configuration of the SMU 313 and the electrical probes 341 of the prober unit 340 (FIG. 3A) to measure a resistance of the exemplary resistance temperature sensor 110 (FIG. 1A) For example, FIG. 5 schematically illustrates an exemplary embodiment of the resistance temperature sensor 110 connected to and between the first electrode 101 and the second electrode 102 on the surface of the substrate 100 (e.g., silicon substrate). In addition, FIG. 5 schematically illustrates an exemplary embodiment of a source measurement unit 520 (or SMU 520) which comprises current generator circuitry 522 and voltage measurement circuitry 524, as well as an exemplary 4-wire electrical probe configuration of, e.g., a probe card, which comprises a first electrical probe 530-1, a second electrical probe 530-2, a third electrical probe 530-3, and a fourth electrical probe 530-4 (which are schematically illustrated as circles that represent probe tips of the corresponding electrical probes).

As schematically illustrated in FIG. 5, the probe tips of the first and second electrical probes 530-1 and 530-2 are aligned and in contact with the first electrode 101, and the probe tips of the third and fourth electrical probes 530-3 and 530-4 are aligned and in contact with the second electrode 102. In this embodiment, the first and second electrodes 101 and 102 serve as contact pads on which the probe tips of the electrical probes 530-1, 530-2, 530-3, and 530-4 are landed to perform resistance measurements of the resistance temperature sensor 110. The first and third electrical probes 530-1 and 530-3 are electrically connected to the voltage measurement circuitry 524 of the SMU 520, and the second and fourth electrical probes 530-2 and 530-4 are electrically connected to the current generator circuitry 522 of the SMU 520.

In some embodiments, the SMU 520 is configured to perform a 4-wire (Kelvin) resistance measurement to measure the resistance of the resistance temperature sensor 110 by a process which comprises (i) utilizing the current generator circuitry 522 to generate and output a current pulse (e.g., DC pulse) to cause a current to flow from the second electrical probe 530-2 to the fourth electrical probe 530-4 (or vice versa) through the resistance temperature sensor 110, and (ii) utilizing the voltage measurement circuitry 524 and the first and third electrical probes 530-1 and 530-3 to detect and measure a voltage drop (V) across the resistance temperature sensor 110 as a result of the current (I) flowing through the resistance temperature sensor 110. The resistance R_{S} of the resistance temperature sensor 110 is determined based on Ohm's Law, i.e., Rₙ=V/I. In some embodiments, the DC current that is used to perform the resistance measurement comprises a pulse amplitude and duration which is sufficient to perform a 4-wire junction resistance measurement, without changing a resistance of the resistance temperature sensor 110 due to localized heating caused by resistive (I²R) heating of the resistance temperature sensor 110.

As noted above, the resistance temperature sensors and associated calibration curves can be utilized to determine thermal profiles for different structured laser beam illumination patterns having different spot geometries and laser powers. In this regard, the exemplary laser annealing system 300 of FIGS. 3A and 3B can be utilized to (i) generate different laser beam illumination patterns to laser anneal on-chip resistance temperature sensors, (ii) measure the resistances of the on-chip resistance temperature sensors after laser annealing, and (iii) utilize the associated calibration curves and calibration data of the resistance temperature sensors to determine the maximum temperatures that the resistance temperature sensors were exposed to as result of the laser annealing to thereby thermal profiles for different laser beam illumination patterns.

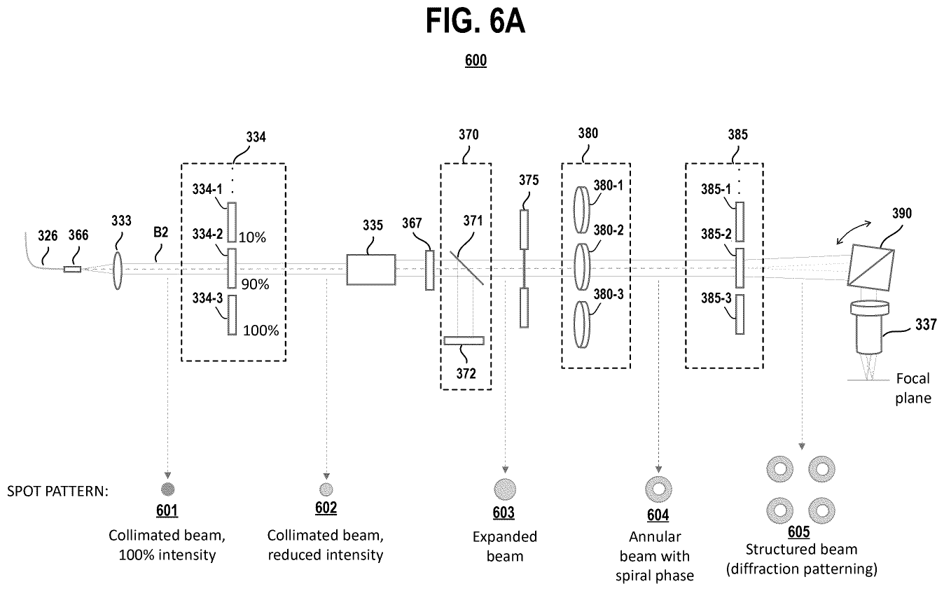

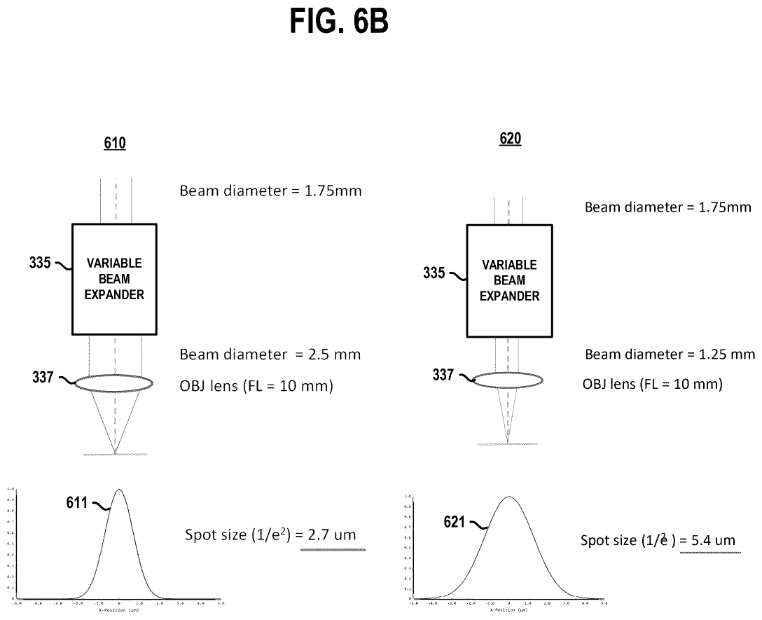

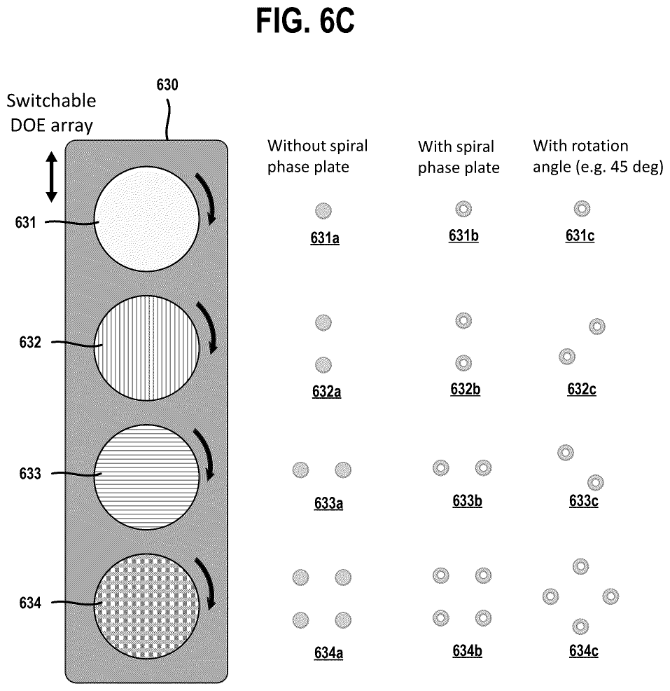

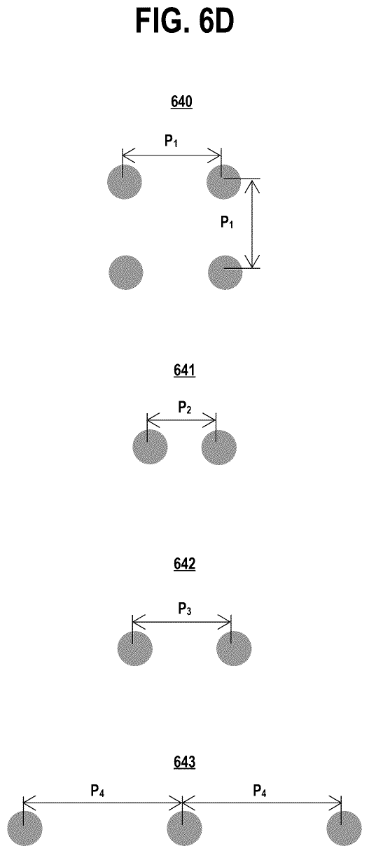

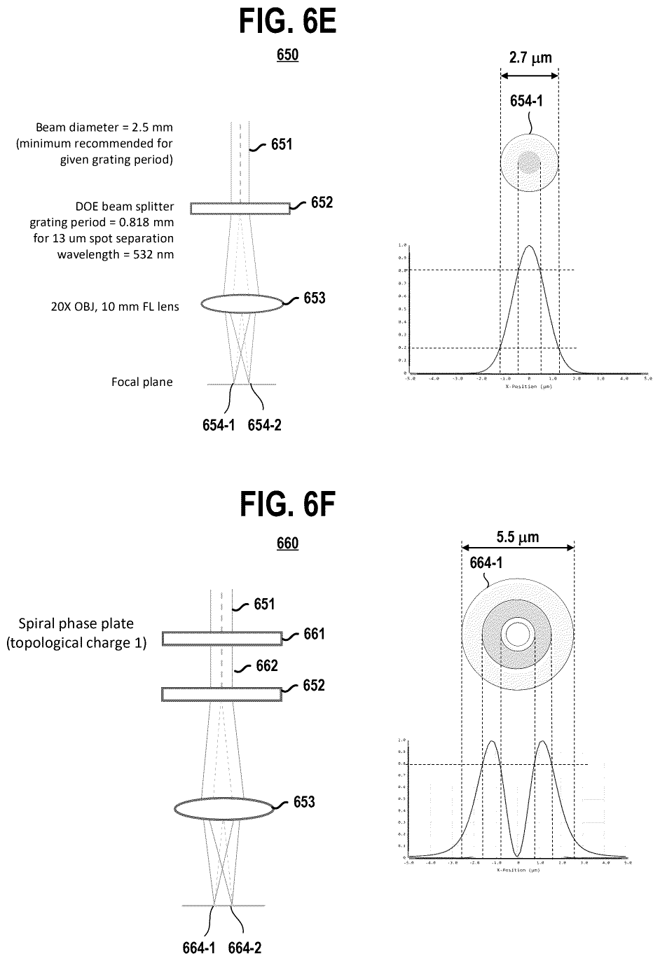

Various exemplary modes of operation of the exemplary laser microscope unit 330 of FIGS. 3A and 3B for generating different structured laser beam illumination patterns will now be discussed in further detail in conjunction with FIGS. 6A, 6B, 6C, 6D, 6E, and 6F. For example, FIG. 6A schematically illustrates a method for generating a laser beam illumination pattern, according to an exemplary embodiment of the disclosure. In particular, FIG. 6A schematically illustrates a method 600 for generating a multi-spot laser beam illumination pattern using the laser microscope unit 330 shown in FIG. 3B, according to an exemplary embodiment of the disclosure. FIG. 6A illustrates various operating modes of various components of the laser microscope unit 330, e.g., the fiber collimator 333, the switchable attenuator device 334, the variable beam expander 335, the spiral phase plate device 380, the switchable DOE device 385, and the XYZ piezo-controlled polarizing beam splitter 390, for generating a desired laser beam illumination pattern and focusing and aligning the laser beam illumination to a given device on the test chip 350.

As schematically illustrated in FIG. 6A, the fiber collimator 333 collimates laser light emitted from the end of the optical fiber 326 to generate a collimated laser beam B2 which provides an initial laser beam spot 601 having an initial diameter and full intensity (100%). In some embodiments, the switchable attenuator device 334 comprises a linear array of optical attenuation elements 334-1, 334-2, and 334-3, which can be selectively placed in the laser beam path to achieve a desired attenuation of the collimated laser beam (e.g., achieve a desired power attenuation level or, alternatively, a desired power throughput level). The switchable attenuator device 334 is configured to be automatically moved back and forth in a linear direction to selectively place one of the optical attenuation elements 334-1, 334-2, and 334-3 in the laser beam path to achieve a desired level of power throughput. FIG. 6A illustrates an exemplary mode of operation in which the switchable attenuator device 334 is operatively controlled to select and place the optical attenuation element 334-2 in the laser beam path to achieve a 90% power throughput level (or 10% attenuation level) and, thereby, generate a collimated laser beam which provides a laser beam spot 602 having the same initial diameter but with 90% of the initial full intensity.

The optical attenuator elements 334-1, 334-2, and 334-3 are formed with different materials that have variable optical densities at the given operating laser light wavelength. For example, in some embodiments, the optical attenuation element 334-3 is configured to provide 100% throughput of laser power (or no laser power attenuation) under certain operation conditions (e.g., when performing a high-power laser anneal operation). The optical attenuation element 334-2 is configured to provide 90% throughput of laser power (or 10% laser power attenuation) under certain operation conditions (e.g., when performing a mid-power laser anneal operation). While not specifically shown, another optical attenuation element can be implemented to provide 80% throughput of laser power (or 20% laser power attenuation) under certain operation conditions (e.g., when performing a low-power laser anneal operation). The optical attenuation element 334-1 is configured to provide 10% throughput of laser power (or 90% laser power attenuation) under certain operation conditions such as, e.g., when utilizing computer vision for imaging a given laser beam illumination pattern for purposes of aligning the laser beam illumination pattern to the center of the FOV of the objective lens or otherwise aligning the laser beam illumination pattern to a given device (e.g., one or more resistance temperature sensors, or one or more Josephson junctions of a quantum device such as a qubit).

Next, FIG. 6A illustrates an exemplary mode of operation in which the variable beam expander 335 is configured to expand the size of the laser beam spot 602 to generate an expanded laser beam spot 603 having a spot diameter which is greater than the spot diameter of the laser beam spot 602. It is to be noted that is some embodiments, the laser beam spots 601, 602, and 603 comprise Gaussian beams, which have high monochromaticity, and an intensity profile (in the transverse plane) which corresponds to a Gaussian function, an exemplary embodiment of which will be discussed in further detail below in conjunction with FIG. 6C.

The spiral phase plate device 380 comprises a plurality of spiral phase plates 380-1, 380-2, and 380-3, which can be selectively placed in the laser beam path to convert the expanded laser beam spot 603 (Gaussian laser spot) to an annular laser beam spot 604 with a given spiral phase that determines the geometry of the annular laser beam spot 604. Each spiral phase plate 380-1, 380-2, and 380-3 is configured to form an annular laser beam profile with a spiral phase distribution, but where the spiral phase plates 380-1, 380-2, and 380-3 are configured to generate different annular laser beam profiles with variable annular and beam hole diameters. FIG. 6A illustrates an exemplary mode of operation in which the spiral phase plate device 380 is operatively controlled to select and place the spiral phase plate 380-2 in the laser beam path to achieve the exemplary annular laser beam spot 604 (or vortex spot). The annular (vortex) laser beam spot 604 comprises “doughnut-shaped” intensity profile and a helical phase structure.

Next, the switchable DOE device 385 comprises a plurality of beam shaping diffractive optical elements 385-1, 385-2, and 385-3, which can be selected to convert the annular laser beam spot 604 into a multi-spot illumination pattern with a given spot geometry. For example, FIG. 6A illustrates an exemplary mode of operation in which the switchable DOE device 385 is operatively controlled to select and place the beam shaping diffractive optical element 385-2 in the laser beam path to generate a laser beam illumination pattern 605 (e.g., quad-spot pattern) comprising four (4) annular laser beam spots based on the annular laser beam spot 604. As noted above, the switchable DOE device 385 comprises an array of laser beam shaping diffractive optical elements which can be selected to generate various types of laser beam illumination patterns (multi-spot patterns) having two or more Gaussian-shaped laser beam spots or two or more annulus-shaped laser beam spots, the details of which will be explained in below. Finally, FIG. 6A schematically illustrates an exemplary mode of operation in which the polarizing beam splitter 390, which is mounted on an automated piezoelectric actuator stage, is positioned to provide a precision alignment of the laser beam illumination pattern 605 to a center of the FOV of the objective lens 337.

Next, FIG. 6B schematically illustrates a method for adjusting a laser beam spot size using a variable beam expander of a laser microscope unit, according to an exemplary embodiment of the disclosure. For example, FIG. 6B schematically illustrates a method 610 for adjusting a laser beam spot size in which the variable beam expander 335 is configured to expand a diameter of an input collimated laser beam, which has a beam diameter of 1.75 mm, to a collimated laser beam having an expanded beam diameter of 2.5 mm. Assuming the objective lens 337 has a focal length (FL) of 10 mm, FIG. 6B graphically illustrates a transverse intensity profile 611 of an exemplary laser beam spot having a Gaussian beam profile and spot size of 2.7 microns. The graph illustrates the transverse intensity profile 611 (e.g., W/m². normalized) as a function of a radial position (in microns) from a laser beam axis (optical centerline of laser beam). In addition, FIG. 6B schematically illustrates a method 620 for adjusting a laser beam spot size in which the variable beam expander 335 is configured to reduce a diameter of an input collimated laser beam, which has a beam diameter of 1.75 mm, to a collimated laser beam having a reduced beam diameter of 1.25 mm. Assuming the objective lens 337 has a focal length (FL) of 10 mm, FIG. 6B graphically illustrates a transverse intensity profile 621 of an exemplary laser beam spot having a Gaussian beam profile and spot size of 5.4 microns.

Next FIG. 6C schematically illustrates a method for generating different laser beam illumination patterns using a switchable DOE array of a laser microscope unit, according to an exemplary embodiment of the disclosure. More specifically, FIG. 6C schematically illustrates an exemplary switchable DOE device 630 comprising a linear array of laser beam shaping diffractive optical elements 631, 632, 633, and 634 which can be selected to generate various types of laser beam illumination patterns (multi-spot patterns) having one or more Gaussian-shaped or annular-shaped laser beam spots. The switchable DOE device 630 can be used to implement the switchable DOE device 385 (FIGS. 3B and 6A) wherein the switchable DOE device 630 is configured to be moved back and forth in a linear direction (as indicted by the double ended arrow) to automatically place one of the laser beam shaping diffractive optical elements 631, 632, 633, and 634 in the laser beam path to achieve a desired laser beam spot pattern. The laser beam shaping diffractive optical elements 631, 632, 633, and 634 are configured to have variable grating structures to generate different spot patterns. The laser beam spot pattern can include a single laser beam spot, a plurality of laser beam spots arranged in a square or rectangular pattern, or a linear pattern, or any combination thereof. The laser beam spots of a given illumination pattern can include a Gaussian profile, or an annular profile with a given spiral phase distribution.

For example, as schematically shown in FIG. 6C, the laser beam shaping diffractive optical element 631 comprises a “null” default element (e.g., a transparent window, or an empty slot) that is configured to allow the beam to pass through with its beam profile unaffected, thus generating a single laser beam spot 631a. The laser beam shaping diffractive optical element 632 comprises a grating structure that is configured to generate a vertical linear pattern of two laser beam spots 632a. The diffractive optical element 633 comprises a grating structure that is configured to generate a horizontal linear pattern of two laser beam spots 633a. The laser beam shaping diffractive optical element 634 comprises a grating structure that is configured to generate a square pattern of four laser beam spots 634a (quad-spot laser beam illumination pattern).

In addition, FIG. 6C further illustrates laser beam illumination patterns 631b, 632b, 633b, and 634b having laser beam spots with annular profiles, which are generated by the respective laser beam shaping diffractive optical elements 631, 632, 633, and 634 when a given spiral phase plate is utilized to generate a laser beam spot with an annular profile, and the annular laser beam spot is passed through the grating structures of the respective laser beam shaping diffractive optical elements 631, 632, 633, and 634. In addition, FIG. 6C further illustrates laser beam illumination patterns 631c, 632c, 633c, and 634c which are generated by rotating the respective laser beam shaping diffractive optical elements 631, 632, 633, and 634 by 45 degrees (in a direction as indicated by the single-ended curves arrows). While FIG. 6C shows an exemplary embodiment of the switchable DOE device 630 comprising a linear array of laser beam shaping diffractive optical elements 631, 632, 633, and 634, in other embodiments, a switchable DOE device can be designed to include a circular array of laser beam shaping diffractive optical elements that are disposed on a rotary stage, which can be selected to generate various types of laser beam illumination patterns (multi-spot patterns).

It is to be understood that the laser beam illumination patterns shown in FIG. 6C are exemplary non-limiting embodiments of different structured laser beam illumination patterns that can be generated to perform laser annealing operations. The exemplary single-spot, dual-spot, and quad-spot laser beam illumination patterns can be further varied based on changing the laser spot widths and spacing (pitch) between laser spots. For example, FIG. 6D schematically illustrates laser beam illumination patterns having different pitches between laser spots, according to exemplary embodiments of the disclosure. In particular, FIG. 6D schematically illustrates an exemplary quad-spot laser beam illumination pattern 640 having laser spots that are separated by a spot pitch P₁. In some embodiments, the spot pitch P₁ can be 13 microns. In other embodiments, structured quad-spot patterns having spot pitches less than or greater than 13 microns can be implemented for laser annealing, as needed, for laser annealing different quantum devices with different Josephson junction geometrics.

In addition, FIG. 6D illustrates an exemplary dual-spot laser beam illumination pattern 641 having laser spots that are separated by a spot pitch P₂, and another exemplary dual-spot laser beam illumination pattern 642 having laser spots that are separated by a spot pitch P₃ which is greater than P₂. For example, in some embodiments, the spot pitch P₂ is 10.3 microns (tight pitch dual-spot pattern), while the spot pitch P₃ is 15.9 microns (medium pitch dual-spot pattern). Moreover, FIG. 6D illustrates an exemplary three-spot laser beam illumination pattern 643 having laser spots that are separated by a spot pitch P₄. In some embodiments, the spot pitch P₄ is 21.0 microns. It is to be noted that the laser beam spots of the exemplary laser beam illumination patterns 640, 641, 642, and 644 can have Gaussian profiles or annular profiles.

When performing laser annealing operations on Josephson junctions, a laser power of 1-2 watts may be used to achieve desired changes in junction resistance. Ideally, the laser spots in a given multi-spot pattern should be tightly spaced (10-15 um separation) for efficient junction heating. For the diffractive optical elements, the spot separation decreases as a grating pitch of the diffractive optical element increases. Preferably, the input beam diameter should be >3× the grating pitch. Moreover, as shown in FIG. 6B, larger input beam diameters lead to smaller focused laser spot sizes. If a laser spot size is too small, substrate damage may occur. In this regard, for tightly spaced DOE spot patterns a spiral (vortex) phase plate can be utilized to generate an annular laser beam spot with double the laser spot size, while lowering the peak irradiance of the focused laser beam spot by about ⅕ as compared to a Gaussian laser beam spot, which significantly reduces the possibility of substrate damage.

For example, FIG. 6E schematically illustrates a process 650 for generating a dual laser beam spot pattern having Gaussian laser beam spots, according to an exemplary embodiment of the disclosure. A collimated laser beam 651 having a beam diameter of 2.5 mm (and a laser wavelength of 532 nm) is passed through a diffractive optical element 652 having a grating period of 0.818 mm to generate two laser beams that are ultimately focused by an objective lens 653 at a focal plane to generate two laser beam spots 654-1 and 654-2 having a spot separation of 13 microns and a Gaussian profile. FIG. 6E further illustrates the laser beam spot 654-1 having a Gaussian profile and spot size of 2.7 microns.

Next, FIG. 6F schematically illustrates a process 660 for generating a dual laser beam spot pattern having annular laser beam spots, according to an exemplary embodiment of the disclosure. The process 660 of FIG. 6F is similar to the process 650 of FIG. 6E, except that the collimated laser beam 651 (having a beam diameter of 2.5 mm and a laser wavelength of 532 nm) is initially passed through a spiral phase plate 661 to convert the profile of the collimated laser beam 651 from a Gaussian profile to a laser beam 662 with an annular profile. The laser beam 662 with the annular profile is passed through the diffractive optical element 652 (having the grating period of 0.818 mm) to generate two laser beams that are ultimately focused by the objective lens 653 at a focal plane to generate two laser beam spots 664-1 and 664-2 having an annular profile. FIG. 6F further illustrates the laser beam spot 664-1 having an annular profile and spot size of 5.5 microns.

As noted above, exemplary embodiments of the disclosure include laser annealing calibration techniques in which resistance temperature sensors are utilized to determine thermal profiles for laser beam illumination patterns that are to be used for laser annealing quantum devices. For example, in some embodiments, a laser annealing calibration process involves fabricating test structures that are representative of quantum devices having Josephson junctions that are to be laser annealed using structured laser beam illumination patterns, wherein a given test structure of a given quantum device (e.g., qubit) implements resistance temperature sensors in place of the Josephson junctions of the give quantum device. The test structures are then laser annealed using structured laser beam illumination patterns at different power levels, and the resistance of the temperature sensors are measured between laser anneal operations to determine the maximum temperatures that the resistance temperature sensors were exposed to as result of the laser annealing and, thereby determine thermal profiles for different structured laser beam illumination patterns.

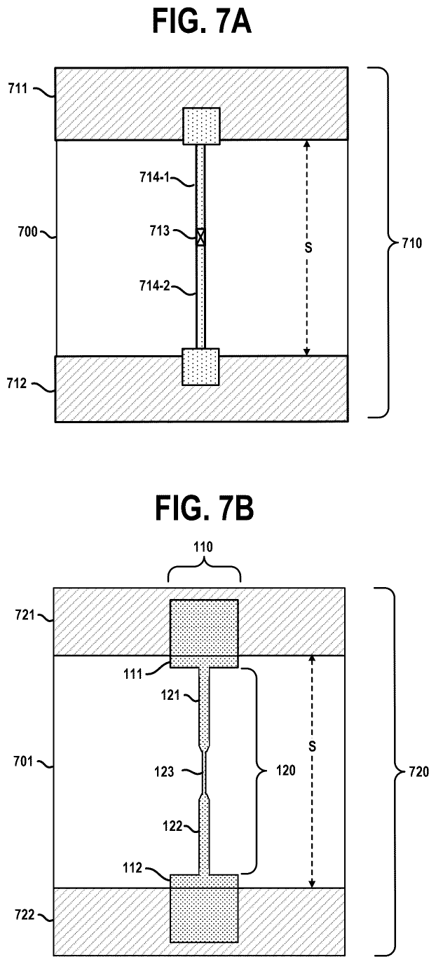

For example, FIG. 7A schematically illustrates an exemplary quantum device comprising a Josephson junction, and FIG. 7B schematically illustrates a corresponding test structure of the quantum device of FIG. 7A with a resistance temperature sensor emulating a size and layout of the Josephson junction of the quantum device, according to exemplary embodiment of the disclosure. In particular, FIG. 7A schematically illustrates quantum device comprising a substrate 700 (e.g., silicon substrate) and a superconducting qubit 710 formed on a surface of the substrate 700. In FIG. 7A, the superconducting qubit 710 comprises a transmon qubit comprising a capacitor and Josephson junction connected in parallel. In particular, the superconducting qubit 710 comprises a first superconducting pad 711, a second superconducting pad 712, and a Josephson junction 713 disposed between, and coupled to, the first and second superconducting pads 711 and 712. As is known in the art, the Josephson junction 713 comprises a first electrode and a second electrode (which are formed of a superconducting metal), and a barrier layer disposed between the first and second electrodes.

The first electrode of the Josephson junction 713 is connected to a first interconnect structure 714-1, and the second electrode of the Josephson junction 713 is connected to a second interconnect structure 714-2. In addition, the first interconnect structure 714-1 is connected to the first superconducting pad 711, and the second interconnect structure 714-2 is connected to the second superconducting pad 712. The first and second interconnect structures 714-1 and 714-2 are formed of a superconducting metal. The first and second superconducting pads 711 and 712 comprise electrodes of a coplanar parallel-plate capacitor structure of the superconducting qubit 710. The Josephson junction 713 functions as a non-linear inductor which, when shunted with the capacitor formed by the first and second superconducting pads 711 and 712, forms an anharmonic LC oscillator with individually addressable energy levels (e.g., two lowest energy level corresponding to the ground state |0) and the first excited state |1)) with a given transition frequency for.

Further, FIG. 7B schematically illustrates a corresponding test structure 720 which emulates the geometric structure (e.g., geometric size and layout) of the superconducting qubit 710 of FIG. 7A. The test structure 720 is formed on a substrate 701 which comprises the same substrate material (e.g., silicon) of the substrate 700 on which the superconducting qubit 710 is formed. The test structure 720 comprises a first electrode 721, a second electrode 722, an instance of the exemplary resistance temperature sensor 110 (FIG. 1A) which is disposed between, and coupled to, the first and second electrodes 721 and 722. In the exemplary embodiment, the first and second electrodes 721 and 722 are designed to emulate the size, layout, and spacing(S) of the first and second superconducting (capacitor) pads 711 and 712 of the superconducting qubit 710. Moreover, the exemplary resistance temperature sensor 110 is designed to emulate the size and placement of the Josephson junction 713 and the first and second interconnects 714-1 and 714-2 between the first and second superconducting (capacitor) pads 711 and 712 of the superconducting qubit 710. In particular, the placement and size of the third (middle) wire portion 123 of the resistance temperature sensor 110 corresponds to the placement and size of the Josephson junction 713 of the superconducting qubit 710.

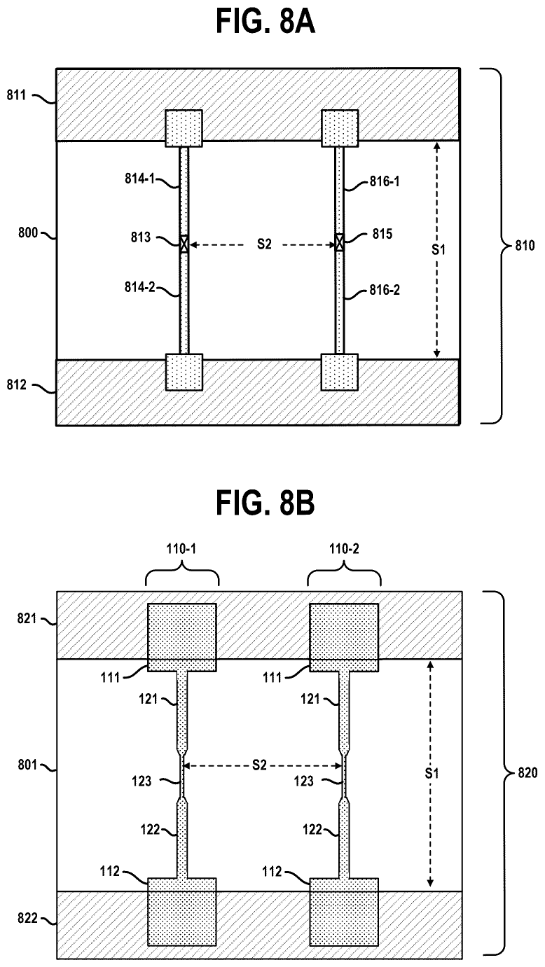

In another exemplary embodiment, FIG. 8A schematically illustrates an exemplary quantum device comprising a pair of Josephson junctions, and FIG. 8B schematically illustrates a corresponding test structure of the quantum device of FIG. 8A with a pair of resistance temperature sensors that emulate the sizes and layout of the pair of Josephson junctions of the quantum device, according to exemplary embodiment of the disclosure. In particular, FIG. 8A schematically illustrates quantum device comprising a substrate 800 (e.g., silicon substrate) and a superconducting qubit 810 formed on a surface of the substrate 800. In FIG. 8A, the superconducting qubit 810 comprises a flux-tunable transmon qubit comprising a capacitor and two Josephson junctions connected in parallel to form a superconducting quantum interference device (SQUID).

More specially, as schematically illustrated in FIG. 8A, the superconducting qubit 810 comprises a first superconducting pad 811, a second superconducting pad 812, a first Josephson junction 813, and a second Josephson junction 815, wherein the first and second Josephson junctions 813 and 815 are disposed between, and coupled to, the first and second superconducting pads 811 and 812. The first Josephson junction 813 is connected to the first and second superconducting pads 811 and 812 by respective first and second interconnect structures 814-1 and 814-2 (which are formed of a superconducting metal). Similarly, the second Josephson junction 815 is connected to the first and second superconducting pads 811 and 812 by respective first and second interconnect structures 816-1 and 816-2 (which are formed of a superconducting metal). The first and second superconducting pads 811 and 812 comprise electrodes of a coplanar parallel-plate capacitor structure of the superconducting qubit 810.

The first and second Josephson junctions 813 and 815 are disposed in a superconducting loop of the SQUID, wherein the superconducting loop is formed by the first and second superconducting pads 811 and 812 and the interconnect structures 814-1, 814-2, 816-1 and 816-2. An external magnetic flux ¢ can be threaded through the superconducting loop of the SQUID to flux-tune the operating frequency of the superconducting qubit 810. The first and second Josephson junctions 813 and 815 of the SQUID can be laser annealed and tuned concurrently by utilizing a suitable laser illumination pattern that is configured to heat the substrate regions surrounding the first and second Josephson junctions 813 and 815.

Further, FIG. 8B schematically illustrates a corresponding test structure 820 which emulates the geometric structure of the superconducting qubit 810 of FIG. 8A. The test structure 820 is formed on a substrate 801 which comprises the same substrate material (e.g., silicon) of the substrate 800 on which the superconducting qubit 810 is formed. The test structure 820 comprises a first electrode 821, a second electrode 822, and first and second instances 110-1 and 110-2 of exemplary resistance temperature sensor 110 (FIG. 1A) which is disposed between, and coupled to, the first and second electrodes 821 and 822. In the exemplary embodiment, the first and second electrodes 822 and 822 are designed to emulate the size, layout, and spacing (S1) of the first and second superconducting (capacitor) pads 811 and 812 of the superconducting qubit 810. Moreover, the exemplary first and second instances 110-1 and 110-2 of resistance temperature sensor 110 are designed to emulate the size, placement, and spacing (S2) of the first and second Josephson junctions 813 and 815 of the superconducting qubit 810. In particular, the placement and size of the third (middle) wire portions 123 of the first and second instances 110-1 and 110-2 of the resistance temperature sensor 110 correspond to the placement and size of the first Josephson junction 813 and the second Josephson junction 815, respectively, of the superconducting qubit 810.

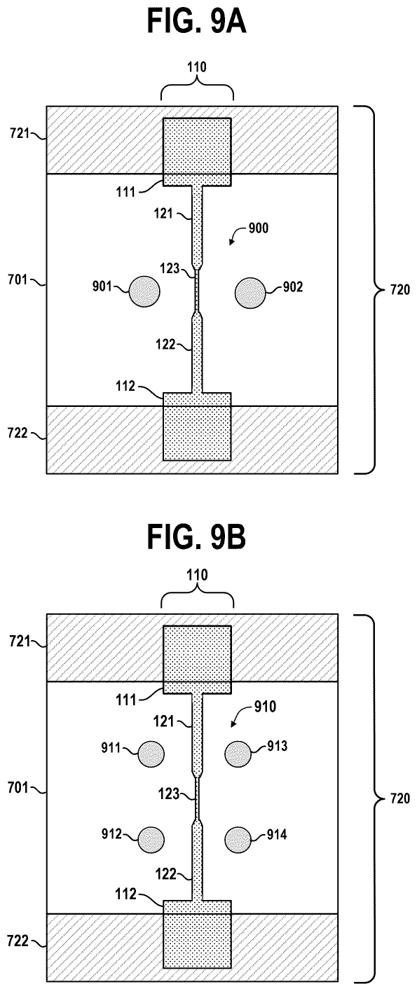

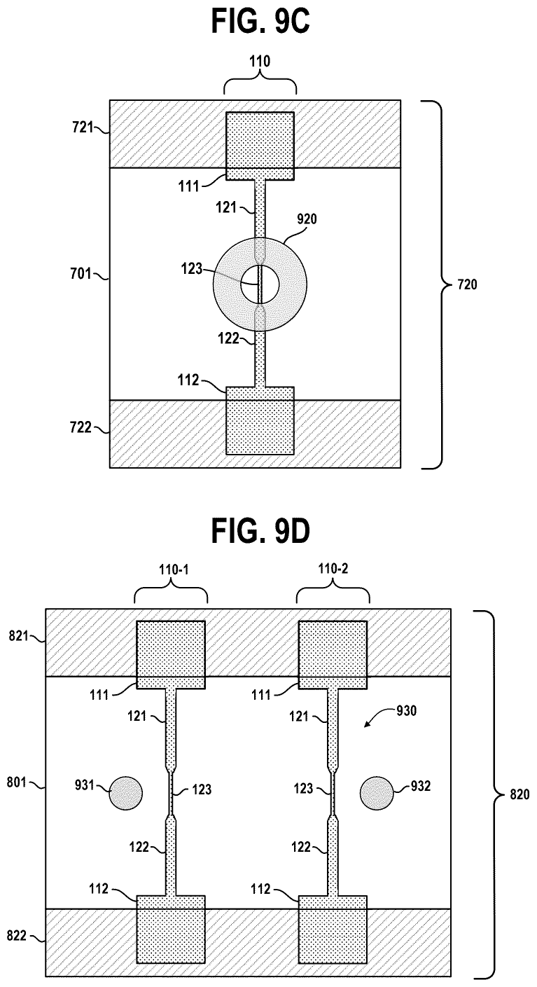

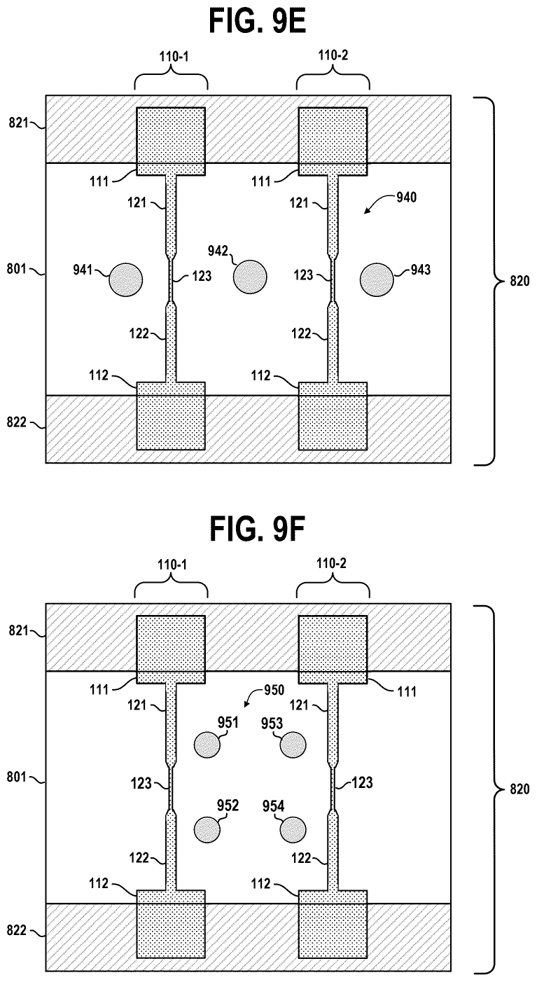

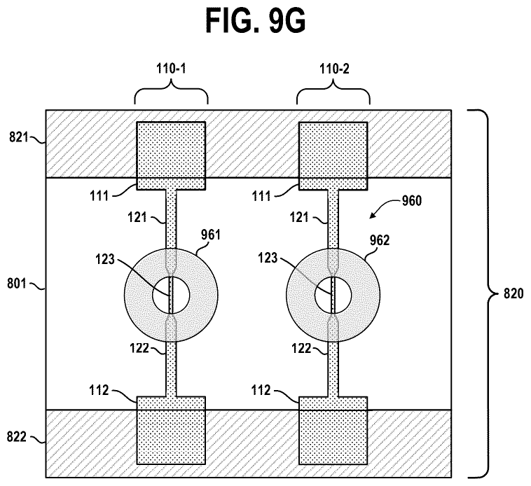

Next, FIGS. 9A, 9B, 9C, 9D, 9E, 9F, and 9G schematically illustrate methods for laser annealing resistance temperature sensors of test structures using various structured laser beam illumination patterns, according to exemplary embodiments of the disclosure. For example, FIG. 9A schematically illustrates a method for laser annealing the exemplary test structure 720 (FIG. 7B) using a dual-spot laser beam illumination pattern 900. The dual-spot laser beam illumination pattern 900 comprises a first laser beam spot 901 that is positioned on one side of the third (middle) wire portion 123 of the resistance temperature sensor 110, and a second laser beam spot 902 that is positioned on an opposite side of the third (middle) wire portion 123 of the resistance temperature sensor 110. As noted above, the third (middle) wire portion 123 of the resistance temperature sensor 110 emulates the size and placement of the Josephson junction 713 of the superconducting qubit 710 of FIG. 7A. The dual-spot laser beam illumination pattern 900 is configured to illuminate (and heat) regions of the upper surface of the quantum chip in proximity to the third (middle) wire portion 123 of the resistance temperature sensor 110, but not directly illuminate the third (middle) wire portion 123 of the resistance temperature sensor 110. The first and second laser beam spots 901 and 902 can have Gaussian profiles or annular profiles. In addition, the first and second laser beam spots 901 and 902 can have spot sizes (e.g., spot widths) that are greater than, or less than, the spot sizes shown in FIG. 9A.

FIG. 9B schematically illustrates a method for laser annealing the exemplary test structure 720 (FIG. 7B) using a quad-spot laser beam illumination pattern 910. The quad-spot laser beam illumination pattern 910 comprises a first laser beam spot 911 and a second laser beam spot 912, which are positioned on one side of the first, second and third wire portions 121, 122, and 123 of the resistance temperature sensor 110, a third laser beam spot 913 and a fourth laser beam spot 914, which are positioned on an opposite side of the first, second and third wire portions 121, 122, and 123 of the resistance temperature sensor 110. The quad-spot laser beam illumination pattern 910 is configured to uniformly heat regions of the upper surface of the substrates 701 in proximity to the third (middle) wire portion 123 of the resistance temperature sensor 110, but not directly illuminate the third (middle) wire portion 123 of the resistance temperature sensor 110. The first, second, third, and fourth laser beam spots 911, 912, 913, and 914 can have Gaussian profiles or annular profiles. In addition, the first, second, third, and fourth laser beam spots 911, 912, 913, and 914 can have spot sizes (e.g., spot widths) that are greater than, or less than, the spot sizes shown in FIG. 9B.

FIG. 9C schematically illustrates a method for laser annealing the exemplary test structure 720 (FIG. 7B) using a single-spot laser beam illumination pattern 920. The single-spot laser beam illumination pattern 920 comprises an annular laser spot profile which is configured to illuminate (heat) a ring-shaped area that surrounds the third (middle) wire portion 123 of the resistance temperature sensor 110, but without directly illuminating the third (middle) wire portion 123 with high laser energy. The exemplary single-spot laser beam illumination pattern 920 with the annular laser spot profile provides a low intensity center region, and can uniformly heat the substrate surrounding the third (middle) wire portion 123 of the resistance temperature sensor 110, without damaging the third (middle) wire portion 123. As noted above, the annular profile of the single-spot laser beam illumination pattern 920 may be achieved using a spiral phase plate with a selected topological charge to engineer the relative dimensions of the annular profile.

Next, FIG. 9D schematically illustrates a method for laser annealing the exemplary test structure 820 (FIG. 8B) using a dual-spot laser beam illumination pattern 930. The dual-spot laser beam illumination pattern 930 comprises a first laser beam spot 931 that is positioned adjacent to the third (middle) wire portion 123 of the first instance 110-1 of resistance temperature sensor 110, and a second laser beam spot 932 that is positioned adjacent to the third (middle) wire portion 123 of the second instance 110-2 of resistance temperature sensor 110. As noted above, the third (middle) wire portions 123 of the first and second instances 110-1 and 110-2 of the resistance temperature sensor 110 emulate the size and placement of the first and second Josephson junction 813 and 815, respectively, of the superconducting qubit 810 of FIG. 8A. The first and second laser beam spots 931 and 932 can have Gaussian profiles or annular profiles. In addition, the first and second laser beam spots 931 and 932 can have spot sizes (e.g., spot widths) that are greater than, or less than, the spot sizes shown in FIG. 9D. In another exemplary embodiment, a dual-spot laser beam illumination pattern having first and second laser spots with a tighter pitch, and disposed within the region between the third (middle) wire portions 123 of the first and second instances 110-1 and 110-2 of the resistance temperature sensor 110, can be implemented to laser anneal the test structure 820.

FIG. 9E schematically illustrates a method for laser annealing the exemplary test structure 820 (FIG. 8B) using a triple-spot laser beam illumination pattern 940. The triple-spot laser beam illumination pattern 940 comprises a first laser beam spot 941 that is positioned adjacent to the third (middle) wire portion 123 of the first instance 110-1 of the resistance temperature sensor 110, a second laser beam spot 942 that is positioned between the third (middle) wire portions 123 of the first and second instances 110-1 and 110-2 of the resistance temperature sensor 110, and a third laser beam spot 943 that is positioned adjacent to the third (middle) wire portion 123 of the second instance 110-2 of the resistance temperature sensor 110. The first, second, and third laser beam spots 941,942, and 943 can have Gaussian profiles or annular profiles. In addition, the first, second, and third laser beam spots 941, 942, and 943 can have spot sizes (e.g., spot widths) that are greater than, or less than, the spot sizes shown in FIG. 9D.

FIG. 9F schematically illustrates a method for laser annealing the exemplary test structure 820 (FIG. 8B) using a quad-spot laser beam illumination pattern 950. The quad-spot laser beam illumination pattern 950 comprises a first, second, third, and fourth laser beam spots 951, 952, 953, and 954, which are positioned between the resistive wires of the first and second instances 110-1 and 110-2 of the resistance temperature sensor 110. The first, second, third, and fourth laser beam spots 951, 952, 953, and 954 can have Gaussian profiles or annular profiles. In addition, the first, second, third, and fourth laser beam spots 951, 952, 953, and 954 can have spot sizes (e.g., spot widths) that are greater than, or less than, the spot sizes shown in FIG. 9F.

FIG. 9G schematically illustrates a method for laser annealing the exemplary test structure 820 (FIG. 8B) using a dual-spot laser beam illumination pattern 960. The dual-spot laser beam illumination pattern 960 comprises a first annular laser beam spot 961 and a second annular laser beam spot 962. The first annular laser beam spot 961 is configured to illuminate a ring-shaped area that surrounds the third (middle) wire portion 123 of the first instance 110-1 of the resistance temperature sensor 110, and the second annular laser beam spot 962 is configured to illuminate a ring-shaped area that surrounds the third (middle) wire portion 123 of the second instance 110-2 of the resistance temperature sensor 110. As noted above, the annular profile of the dual-spot laser beam illumination pattern 960 may be achieved using a spiral phase plate with a selected topological charge to engineer the relative dimensions of the annulus profile, and a suitable DOE to generate the dual laser beam spots.

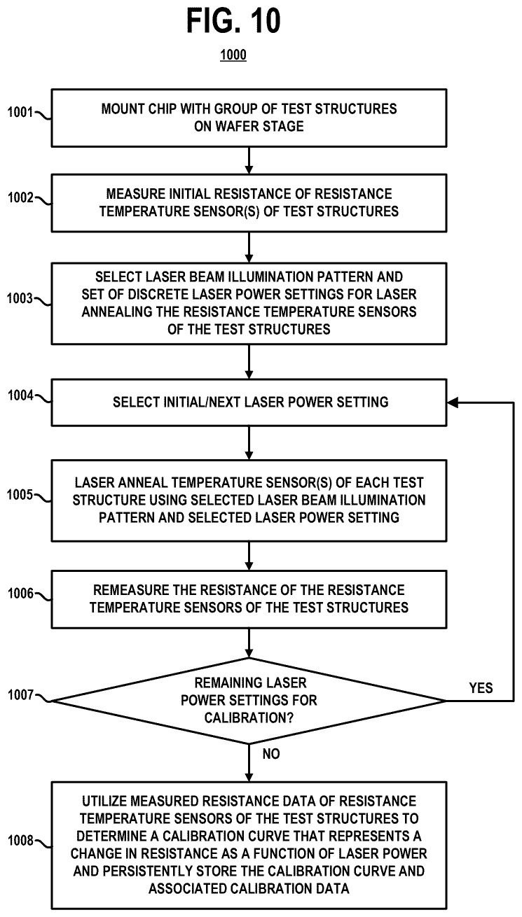

As noted above, exemplary embodiments of the disclosure include laser annealing calibration methods in which test structures (e.g., the exemplary test structures 720 and 820 (FIGS. 7B and 8B) are laser annealed using structured laser beam illumination patterns (e.g., as shown in FIGS. 9A-9G) at different power levels, and the resistance of the temperature sensors of the test structures are measured between laser anneal operations to determine the maximum temperatures that the resistance temperature sensors were exposed to as result of the laser annealing. The measured resistance data comprises laser annealing calibration data which is analyzed to determine thermal profiles for the structured laser beam illumination patterns. For example, FIG. 10 illustrates a flow diagram of a method for performing a calibration process to determine thermal profiles of structured laser beam illumination patterns, according to an exemplary embodiment of the disclosure. More specifically, FIG. 10 illustrates a calibration process 1000 for performing trial thermal annealing operations on resistance temperature sensors of test structures, which emulate the geometric structures (e.g., geometric size and layout) of Josephson junctions of corresponding quantum devices (e.g., qubits), to obtain calibration data that is processed to determine thermal profiles for structured laser beam illumination patterns.

In some embodiments, the calibration process 1000 of FIG. 10 is implemented using the laser annealing system 300 of FIGS. 3A and 3B. For example, an initial step of the calibration process 1000 comprises mounting a test chip on the wafer stage 342, wherein the test chip comprises a group of test structures formed on a substrate (block 1001). In some embodiments, the group of test structures comprise multiple instances of a given test structure with one or more resistance temperature sensors, wherein the test structures are constructed to emulate the size, placement, geometry, etc., of a given quantum device (e.g., superconducting qubit) that are to be thermally annealed. For example, for purposes of illustration, it is assumed that the group of test structures comprises multiple instances (nominally identical structures) of the exemplary test structure 720 (FIG. 7B) which emulates the superconducting qubit 710 (FIG. 7A).

The calibration process proceeds by measuring the initial resistance R_{INIT} of the resistance temperature sensors of the test structures of the group of test structures (block 1002). It is to be noted that for the calibration process 1000, it is assumed that calibration data has been obtained, e.g., via the calibration process 400 of FIG. 4, with regard to the resistance/temperature profile of the resistance temperature sensors of the test structures, which are nominally identical (as constructed) to the test group of resistance temperature sensors used the calibration process 400. In this regard, the average initial resistance R_{INIT} of the nominally identical resistance temperature sensors used in, e.g., the calibration process 400 of FIG. 4 is assumed to be the same or similar to the initial resistance R_{INIT} of the resistance temperature sensors of the group of test structures. By measuring the initial resistance of the resistance temperature sensors of the test structures (block 1002), a determination can be made that the resistance temperature sensors of the given group of test structures will have the same or similar resistance/temperature profile of the resistance temperature sensors as determined via the calibration process 400.

In some embodiments, the initial resistance of the resistive temperature sensors of the test structures is measured using the prober unit 340 and SMU 313 to perform a 4-wire (Kelvin) resistance measurement to measure the initial resistance River of each resistance temperature sensor of each test structure in the group of test structures. In some embodiments, the initial resistance R_{INIT} of each resistance temperature sensor is measured at a target temperature, e.g., 0° C., wherein the test chip is actively cooled to the target temperature via the thermal chuck to perform the resistance measurements. In some embodiments, the resistance measurements are performed using the exemplary 4-wire (Kelvin) resistance measurement process as discussed above in conjunction with FIG. 5.

Next, a set of trial laser annealing operations are performed on each test structure in the group of test structures. In particular, the calibration process 1000 proceeds to select a laser beam illumination pattern and set of discrete laser power settings, P₁, P₂ . . . , Pₓ, for laser annealing each test structure using the selected laser beam illumination pattern at each laser power setting (block 1003). For example, in some embodiments, for purposes of illustration, it is assumed that the selected laser beam illumination pattern comprises a quad-spot pattern (e.g., the quad-spot laser beam illumination pattern 910, FIG. 9B) with the laser spots having a given spot diameter (e.g., 4.7 microns) and spot pitch (e.g., 13 microns). Further, in some embodiments, the laser power settings, P₁, P₂, . . . , Pₓ, can include a set of x discrete of laser power settings, which begin at P₁=0.5 W, and which increase at a desired increment of laser power, up to a maximum laser power setting Pₓ=2.8 W.

The trial laser annealing operations begin by selecting the initial laser power setting P₁ (block 1004), and laser annealing the resistance temperature sensor(s) of the test structures in the group of test structures using the selected laser beam illumination pattern and the selected laser power setting (block 1005). More specifically, the calibration process 1000 proceeds to configure the laser unit 320 and the laser microscope unit 330 of the laser annealing system 300 (FIGS. 3A and 3B) to enable laser annealing of each test structure in the group of test structures using the selected laser beam illumination pattern and selected laser power setting. In an exemplary embodiment, the test structures are laser annealed in sequence. For example, the calibration process 1000 initiates control operations to cause the laser microscope unit 330 and the prober unit 340 to focus and align to a given test structure in the group of test structures for performing a laser anneal operation on the given test structure. The focusing and alignment ensures that the target resistance temperature sensor of the given test structure is properly aligned within the FOV of the laser microscope unit 330 and properly focused at a target focal plane for the purpose of illuminating the test structure with the selected laser beam illumination pattern and laser power setting to laser anneal the resistance temperature sensor(s) of the given test structure. The alignment, focus, and laser anneal operations are then repeated for each remaining test structure in the group of test structures, so that each test structure within the group of test structures is eventually laser annealed using the selected laser beam illumination pattern at the selected laser power setting.

Subsequent to the laser annealing of each test structure within the group of test structures using the selected laser beam illumination pattern at the selected laser power setting, the calibration process 1000 proceeds to remeasure the resistance of the resistance temperature sensors of the test structures of the group of test structures and to record the measured resistance values (block 1006). The resistances of the temperature sensors are measured using the same techniques as discussed above.

The laser annealing and resistance measurement operations (blocks 1005 and 1006) are repeated for each remaining laser power setting. For example, if there are one or more remaining laser power settings for calibration (affirmative determination in block 1107), the calibration process 1000 proceeds to select the next laser power setting (return to block 1004), and configure the laser unit 320 and the laser microscope unit 330 of the laser annealing system 300 (FIGS. 3A and 3B) to enable laser annealing of each test structure in the group of test structures using the selected laser beam illumination pattern with the next selected laser power setting. Each test structure in the group of test structures is then laser annealed again using the selected laser beam illumination pattern and the next selected laser power setting (block 1005), and the resistances of the resistive temperature sensors of the test structure are remeasure and recorded in association with the next selected laser power setting. It is to be noted that each successive laser annealing operation on a given test structure using a higher laser power setting (while using the same laser beam illumination pattern) results in the resistance temperature sensors of the test structures being exposed to a higher maximum temperature, which allows the calibration process 1000 to track the change in resistance of the temperature sensors as the laser power is increased. It is to be further noted that all laser anneal operations are performed using the same anneal time.

On the other hand, if there are no remaining laser power settings for calibration (negative determination in block 1007), the calibration process 1000 proceeds to utilize the measured resistance data (calibration data) of the resistance temperature sensors of the group of test structures determine a calibration curve that represents the resistance of the resistance temperature sensors as a function of laser power for the given laser beam illumination pattern, and persistently store the calibration curve and associated calibration data in, e.g., the database of calibration data 316, FIG. 3A (block 1008). For example, in some embodiments, the calibration curve is determined by computing a plurality of data points, and utilizing statistical methods and curve fitting techniques (such as those discussed above) to fit the data points to a calibration curve which represents the resistance of the resistance temperature sensors of the test structures as a function of laser power for the given laser beam illumination pattern. The data points include (i) an initial data point that represents an average of the initially measured resistances of the resistance temperature sensors of the test structures (assuming zero (0) laser power), and (ii) a data point for each laser power setting, wherein the data point for a given laser power setting represents an average of the measured resistances of the resistance temperature sensors of the test structures after laser annealing the resistance temperature sensors using the selected laser beam illumination pattern at the given laser power setting.

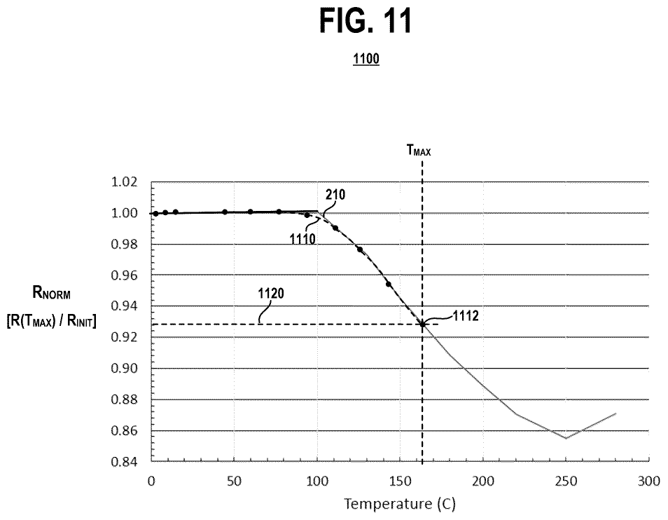

It is to be noted that other calibration curves can be generated based on the laser calibration data that is acquired for a given laser beam illumination pattern using the exemplary calibration process 1000 of FIG. 10. For example, a calibration curve for a given laser beam illumination pattern can be generated which represents the resistance of the resistance temperature sensors as a function of the maximum temperature to which the resistance temperature sensors are exposed as a result of the laser annealing. By way of example, FIG. 11 illustrates a graph 1100 which, similar to the graph 200 of FIG. 2, plots a normalized resistance RNORM (Y-axis) as a function of temperature in degrees Celsius (X-axis).

Moreover, FIG. 11 depicts the calibration curve 210 of FIG. 2, and a calibration curve 1110 which is overlayed over the calibration curve 210 by aligning the knees of the curves 210 and 1110. As noted above, the calibration curve 210 represents the normalized resistance RNORM as a function of temperature for a given the exemplary resistance temperature sensor 110 (FIG. 1A), wherein the curve 210 is generated using calibration data acquired by, e.g., performing the exemplary calibration process 400 of FIG. 4 on a test group of nominally identical resistance temperature sensors, which are thermally annealed (bulk anneal process) using a thermal chuck.

On the other hand, the calibration curve 1110 is a dashed-line curve which represents normalized resistance as a function of temperature, which is computed from calibration data acquired with regard to the resistance temperature sensors of the nominally identical test structures (which emulate qubits with single Josephson junctions) that are laser annealed using, e.g., a quad-spot laser beam illumination pattern, as part of the exemplary calibration process 1000 of FIG. 10. The calibration curve 1110 comprises a plurality of data points (e.g., data point 1112) that are represented as dots on the dashed-line curve, wherein each data point corresponds to an average of the measured resistances of the resistance temperature sensors the group of test structures that were laser annealed using a quad-spot laser beam illumination pattern at a given laser power setting with the same exposure time. In this regard, each data point represents an increasing thermal load with increasing laser power.

In some embodiments, with regard to the data points for the calibration curve 1110, the Y axis represents values of

$${R}_{NORM} = \frac{{R}_{AVG}}{{R}_{INT\_AVG}} ,$$

where R_{INT_AVG} denotes an average of the measured initial resistances of the resistance temperature sensors of the group of test structures before performing laser annealing calibration operations, and where R_{AVG} denotes an average of the measured resistances of the resistance temperature sensors of the group of test structures after performing laser annealing calibration operations using the quad-spot laser beam illumination pattern at a given laser power setting. For example, the data point 1112 of the calibration curve 1110 represents the

$${R}_{NORM} = \frac{{R}_{AVG}}{{R}_{INT\_AVG}}$$

value which is computed based on the measured resistances of the resistance temperature sensors of the group of test structures after laser annealing the test structures using the quad-spot laser beam illumination pattern at a laser power setting of 1.7 W. FIG. 11 illustrates a horizontal line 1120 that intersects the data point 1112, which indicates that the resistance temperature sensors reach a maximum temperature (T_{MAX}) of approximately 160° C. with a resistance decrease of about-7% as a result of being laser annealed using a quad-spot laser beam illumination pattern (such as shown in FIG. 9B) at a lower power setting of 1.7 W.

It is to be noted that for ease of illustration and explanation, the calibration process 1000 of FIG. 10 is described in the context of performing a calibration process to obtain calibration data for a specific laser beam illumination pattern (e.g., quad-spot pattern) having laser spots with a specified spot size and spot pitch, over a range of discrete power levels. However, the calibration process 1000 of FIG. 10 can be performed to obtain calibration data for other structured laser beam illumination patterns. A given test chip can have multiple groups of test structures, wherein each group of test structures is utilized to obtain calibration data for a given structured laser beam illumination pattern have a unique combination of (i) spot pattern (e.g., single, double, triple, quad-spot, etc.), (ii) spot size, (iii) spot pitch, and/or (iv) spot profile (e.g., annular or Gaussian, etc.), over a range of discrete power levels, wherein the range of discrete power levels can be the same or different, depending on the given structured laser beam illumination pattern.

For example, the test chip can have multiple groups of the exemplary test structure 720 of FIG. 7B (which emulates a qubit with a single Josephson junction), where each group of such test structures is utilized to obtain calibration data for a given unique structured laser beam illumination pattern, e.g., the dual-spot laser beam illumination pattern 900 shown in FIG. 9A, the single-spot laser beam illumination pattern 920 shown in FIG. 9C, etc. Further, the test chip can have multiple groups of the exemplary test structure 820 of FIG. 8B (which emulates a qubit with two Josephson junctions), where each group of such test structures is utilized to obtain calibration data for a given unique structured laser beam illumination pattern, e.g., the dual-spot laser beam illumination pattern 930 shown in FIG. 9D, the triple-spot laser beam illumination pattern 940 shown in FIG. 9E, the quad-spot laser beam illumination pattern 950 shown in FIG. 9F, the dual-spot annular laser beam illumination pattern 960 shown in FIG. 9G, etc.

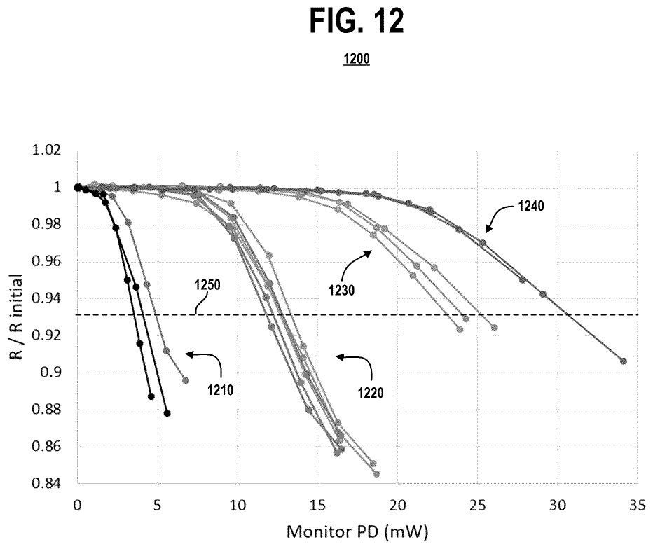

In this regard, the exemplary calibration process 1000 of FIG. 10 can be implemented for each of a plurality of unique structured laser beam illumination patterns, and for a variety of unique test structures with different geometric configurations of resistance temperature sensors that emulate Josephson junctions of quantum device, to thereby generate a set of calibration curves that represent resistance as a function of power level setting for the plurality of unique structured laser beam illumination patterns. For example, FIG. 12 illustrates a set of calibration curves that represent resistance as a function of power level setting for a plurality of unique structured laser beam illumination patterns. In particular, FIG. 12 illustrates a graph 1200 which plots a normalized resistance RNORM (Y-axis) as a function of laser power (X-axis). In FIG. 12, the laser power is based on a sampled laser power (mW) by, e.g., the power monitor 370 of the laser microscope unit 330 (FIG. 3B), where a sampled power level of 25 mW corresponds to an actual power level of about 1.9 W.

In addition, FIG. 12 illustrates a first set of calibration curves 1210, a second set of calibration curves 1220, a third set of calibration curves 1230, and a fourth set of calibration curves 1240, which can be generated using the exemplary calibration process 1000 of FIG. 10. The first set of calibration curves 1210 represent the normalized resistance RNORM as a function of laser power for resistance temperature sensors of test structures (e.g., test structure 720, FIG. 7B), which are obtained by laser annealing the temperature sensors with different single-spot annular laser beam illumination patterns having different spot sizes. The second set of calibration curves 1220 represent the normalized resistance RNORM as a function of laser power for resistance temperature sensors of test structures (e.g., test structure 720, FIG. 7B), which are obtained by laser annealing the temperature sensors using different dual-spot annular laser beam illumination patterns having different unique combinations of spot sizes and spot pitch (e.g., 10 micron and 13 micron). The third set of calibration curves 1230 represent the normalized resistance RNORM as a function of laser power for resistance temperature sensors of test structures (e.g., test structure 720, FIG. 7B), which are obtained using different quad-spot annular laser beam illumination patterns having different unique combinations of spot sizes. The fourth set of calibration curves 1240 represent the normalized resistance RNORM as a function of laser power for resistance temperature sensors of test structures (e.g., test structure 720, FIG. 7B), which are obtained using different triple-spot annular laser beam illumination patterns having different unique combinations of spot sizes.

It is to be noted that each curve shown in FIG. 12 comprises a plurality of data points, wherein each data point corresponds to an average of the measured resistances of the resistance temperature sensors of a given group of test structures that were laser annealed using a given laser beam illumination pattern at a given laser power setting with the same exposure time. Each curve begins with a flat portion which shows that the initial resistances of the temperature sensors remain constant over a certain range of low laser power settings, which is followed by a decreasing portion which shows that the resistance of the temperate sensors decrease with increasing power levels.

In addition, FIG. 12 illustrates a horizontal line 1250 (which corresponds to the horizontal line 1120 of FIG. 11) that intersects each curve at a given point on the curve which indicates a resistance decrease of about-7% which results from the temperature sensors reaching a maximum temperature of approximately 160° C. (based on the calibration data shown in FIG. 11) as a result of being laser annealed by the unique laser beam illumination patterns associated with the respective curves at different power levels. FIG. 12 illustrates that resistance changes of resistance temperature sensors occur for relatively low power levels when the resistance temperature sensors are laser annealed using single-spot or dual-spot laser beam illumination patterns, while resistance changes of resistance temperature sensors occur for relatively higher power levels when the resistance temperatures sensors are laser annealed using triple-spot or quad-spot laser beam illumination patterns.

The exemplary sets of calibration curves 1210, 1220, 1230, and 1240 as shown in FIG. 12 can be utilized to determine the laser power level needed for a given laser beam illumination pattern to reach a target resistance of a temperature sensor that is laser annealing using the given laser beam illumination pattern, and the target resistance of the temperature sensor is utilized to determine the maximum temperature to which the resistance temperature sensor is exposed (via, e.g., calibration curve. 210 of FIG. 2) as a result of being laser annealed using the given laser beam illumination pattern. In this regard, the exemplary calibration curves shown in FIGS. 2, 11, and 12 are utilized to infer the maximum temperature that a given Josephson junction of a given quantum device will reach when laser annealed using a given laser beam illumination pattern at a given power level setting.

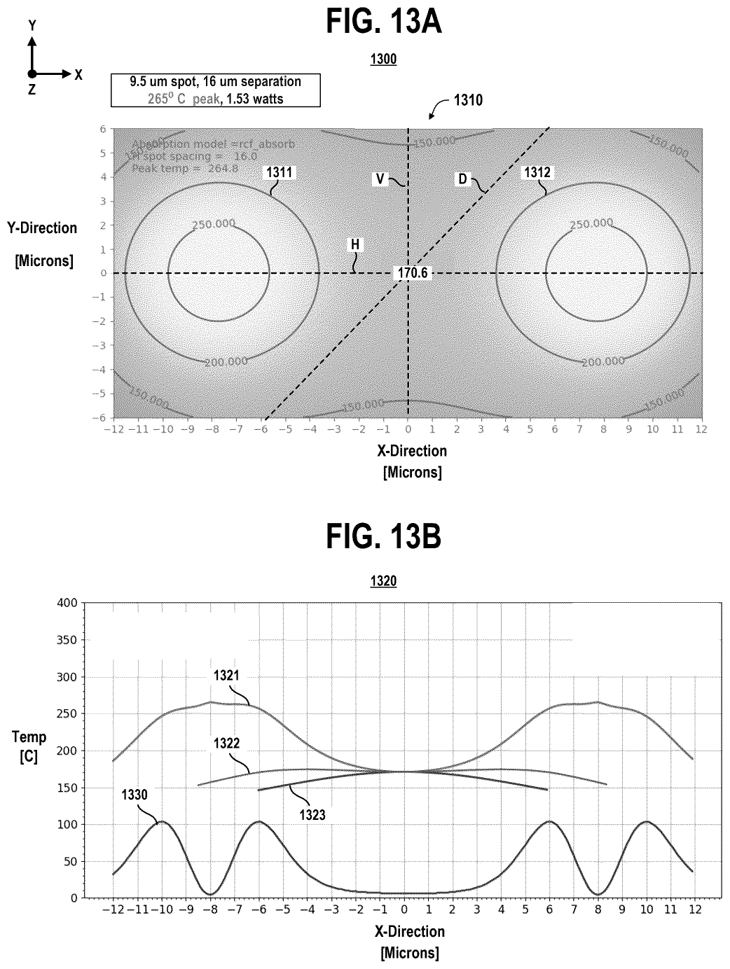

In other embodiments, thermal profiles of different laser beam illumination patterns are estimated using thermal simulation and analysis software tools, wherein the simulated thermal profiles of the different laser beam illumination patterns can be verified against corresponding thermal profiles of corresponding laser beam illumination patterns that are determined from calibration data obtained by laser annealing resistance temperature sensors using different laser beam illumination patterns. For example, FIGS. 13A and 13B illustrate a simulated thermal profile of a laser beam illumination pattern, according to an exemplary embodiment of the disclosure. In particular, FIGS. 13A and 13B illustrate a simulated thermal profile 1300 of a dual-spot laser beam illumination pattern 1310 when illuminated on a surface of substrate, e.g., a silicon substrate.

As shown in FIG. 13A, the dual-spot laser beam illumination pattern 1310 comprises a first laser spot 1311 and a second laser spot 1312, which have a vortex spot profile, a spot size of 9.5 microns, and a spot pitch of 16 microns. FIG. 13A shows a simulated thermal profile 1300 (via different temperature in different regions on a surface of the silicon substrate) which is generated as a result of a thermal model simulation in which the surface of the silicon substrate is irradiated with the dual-spot laser beam illumination pattern 1310 at a laser power of 1.53 W. FIG. 13A illustrates a horizontal line H, a vertical line V, and a diagonal line D, which intersect at an origin point (0,0). FIG. 13A shows the simulated thermal profile on a portion of the substrate surface ranging from −12.0 microns to +12.0 microns (X-direction), and ranging from −6.0 microns to +6.0 microns (Y-direction). It is to be noted that the origin point (0,0) shown in FIG. 13A represents a “center point” of the dual-spot laser beam illumination pattern 1310.

FIG. 13B is graph 1320 which comprises simulated curves 1321, 1322, 1323, and 1330. The simulated curve 1321 represents the temperature of the substrate surface at locations in the X-direction along the horizontal line H in FIG. 13A. The simulated curve 1322 represents the temperature of the substrate surface at locations in the direction along the diagonal line D in FIG. 13A. The simulated curve 1323 represents the temperature of the substrate surface at locations in the Y-direction along the vertical line V in FIG. 13A. The simulated curve 1330 represents the laser intensity profile of the dual-spot laser beam illumination pattern 1310 (comprising the annular-shaped first and second laser spots 1311 and 1312) at locations in the X-direction along the horizontal line H in FIG. 13A.

FIGS. 13A and 13B show that the substrate surface reaches temperature of 170.6° C. at the center point (0,0) between the first and second laser spots 1311 and 1312, and that the substrate surface reaches a maximum temperature of 264. 8° C. at the x-y center points (−8, 0) and (+8.0, 0) of the first and second laser spots 1311 and 1312. In this regard, the simulated thermal profile of the dual-spot laser beam illumination pattern 1310 (as shown in FIGS. 13A and 13B) indicates that a given Josephson junction (formed on a silicon substrate) will reach a maximum temperature of about 170.6° C. when laser annealed using a structured dual-spot laser beam illumination pattern corresponding to the dual-spot laser beam illumination pattern 1310 shown in FIG. 13A at the given laser power of about 1.53 W, with the Josephson junction disposed in the center region between the first and second laser spots.

While FIGS. 13A and 13B illustrate a simulated thermal profile 1300 associated with a given dual-spot laser beam illumination pattern, it is to be noted that simulated thermal profiles can be generated in the same manner for a plurality of unique structured laser beam illumination patterns at different laser power settings to build a database of unique structured laser beam illumination patterns and associated profiles, which are used for configuring, e.g., laser annealing operations for tuning the junction resistances of Josephson junctions of quantum devices. To verify the accuracy of a given simulated thermal profile of a given structured laser beam illumination pattern, the simulated thermal profile of the given structured laser beam illumination pattern can be compared against an actual thermal profile that is determined from calibration data that is obtained via the exemplary calibration process 400 and 1000, by laser annealing resistance temperature sensors with actual laser beam illumination patterns that are configured to correspond to the simulated laser beam illumination patterns.

In other embodiments, the thermal profiles associated with various structured laser beam illumination patterns can be determined by laser annealing groups of resistance temperature sensors to generate thermal profiles curves (such as shown in FIG. 13B) based on substrate temperature data which is inferred from measured resistance values of the resistance temperature sensors after thermal annealing using structured laser beam illumination pattern. For example, in some embodiments, a linear array of multiple resistance temperature sensors (e.g., 5-10 or more resistance temperature sensors) can be formed on a substrate, and then concurrently irradiated with a given structured laser beam illumination pattern at a given laser power, with a center point of the structured laser beam illumination pattern (e.g., a center point of a laser spot of a single-spot laser beam illumination pattern, or center point between laser spots of a multi-spot laser beam illumination pattern) aligned to a given resistance temperature sensor located in a middle of the linear array. The resistance of each resistance temperature sensor in the array is then measured to determine the maximum temperature to which the given resistance temperature sensor was exposed as a result of being thermally annealed by the given structured laser beam illumination pattern at the given laser power, based on the calibration data (e.g., calibration curve 210, FIG. 1) associated with the resistance temperature sensors.

In other embodiments, a single resistance temperature sensor can be formed on a substrate, and then sequentially irradiated using a given structured laser beam illumination pattern at a given laser power, with a center point of the structured laser beam illumination pattern having different offsets (X₁, X₂, . . . , Xᵢ) from the location of the single resistance temperature sensor. With this process, the center point of the structured laser beam illumination pattern can be initially disposed at a first offset X₁ which is furthest from the location of the single resistance temperature sensor (where the thermal gradient is assumed to be at the lowest). Thereafter, the center point of the structured laser beam illumination pattern can be disposed at increasing smaller offsets X₂, . . . , Xᵢ from the location of the single resistance temperature sensor, providing an increasing temperature gradient as the center of the structured laser beam illumination pattern is disposed closer to the single resistance temperature sensor.

In particular, at each offset location of the structured laser beam illumination pattern, the single resistance temperature sensor is thermally annealed by irradiating the substrate with the given structured laser beam illumination pattern at the given laser power, followed by measuring the resistance of the single resistance temperature sensor. With this process, the measured resistance values of the single resistance temperature sensor are mapped to corresponding temperature values which indicate the maximum temperatures to which the single resistance temperature sensor was exposed as a result of being laser annealed by the structured laser beam illumination pattern at the given laser power at each of the offsets (X₁, X₂ . . . , Xᵢ) from the resistance temperature sensor. The maximum temperatures determined at the various offsets (X₁, X₂ . . . , Xᵢ) are then used as data points that are fit to a thermal profile curve which represents the thermal profile of the given structured laser beam illumination pattern at the given laser power as a function of the offset of the center point of the given structured laser beam illumination pattern, similar to, e.g., simulated curve 1321 as shown in FIG. 13B.

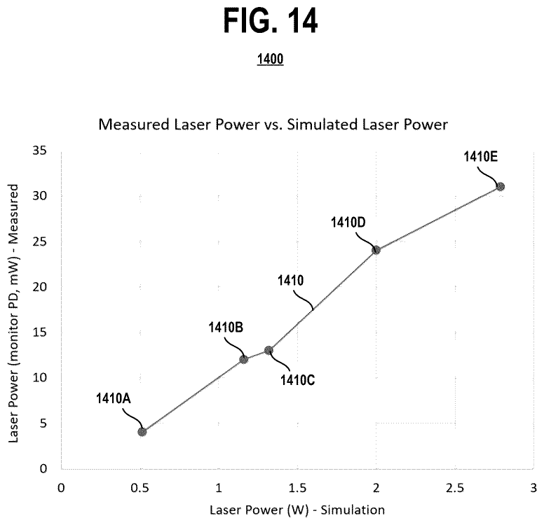

Various methods can be used to compare and verify the accuracy of a simulated thermal profile and corresponding measured thermal profile for a given structured laser beam illumination pattern at a given power level. For example, FIG. 14 is a graph 1400 which compares a measured laser power to a simulated laser power for different structured laser beam illumination patterns, according to an exemplary embodiment of the disclosure. More specifically, FIG. 14 illustrates a simulated laser power (W) of a simulated laser beam illumination pattern (X-axis) to reach a target substrate temperature (e.g., 170° C.) at a center point of the simulated laser beam illumination pattern, and a measured laser power (i.e., sampled laser power (mW) by power monitor) of a corresponding laser beam illumination pattern (Y-axis) to reach a similar target substrate temperature (e.g., 160° C.). at a center point of the laser beam illumination pattern (as determined based on the resistance of resistance temperatures sensor that is thermally annealed using the laser beam illumination pattern). As noted above, the measured laser power (Y-axis) is based on a sampled laser power (mW) by, e.g., the power monitor 370 of the laser microscope unit 330 (FIG. 3B), where a sampled power level of 25 mW corresponds to an actual power level of about 1.9 W.

FIG. 14 illustrates a curve 1410 which comprises a plurality of data points 1410A, 1410B, 1410C, 1410D, and 1410E. The data point 1410A corresponds to a single-spot laser beam illumination pattern with a spot size of 6.8 microns. The data point 1410B corresponds to a dual-spot laser beam illumination pattern with a spot pitch of 10 microns. The data point 1410C corresponds to a dual-spot laser beam illumination pattern with a spot pitch of 13 microns. The data point 1410D corresponds to a quad-spot laser beam illumination pattern with a spot pitch of 13 microns. The data point 1410E corresponds to a triple-spot laser beam illumination pattern with a spot pitch of 21 microns. The curve 1410 has a near linear profile which indicates a good correlation between the simulation results and the measured results (based on the resistance temperature sensors). In this regard, FIG. 14 illustrates that the use of the exemplary resistance temperature sensors as part of a calibration process to acquire calibration data (e.g., calibration process 1000 of FIG. 10 to obtain calibration curves 1210, 1220, 1230, and 1240 as shown in FIG. 12) are an effective and accurate way to determine thermal profiles of laser beam illumination patterns for laser annealing quantum devices.

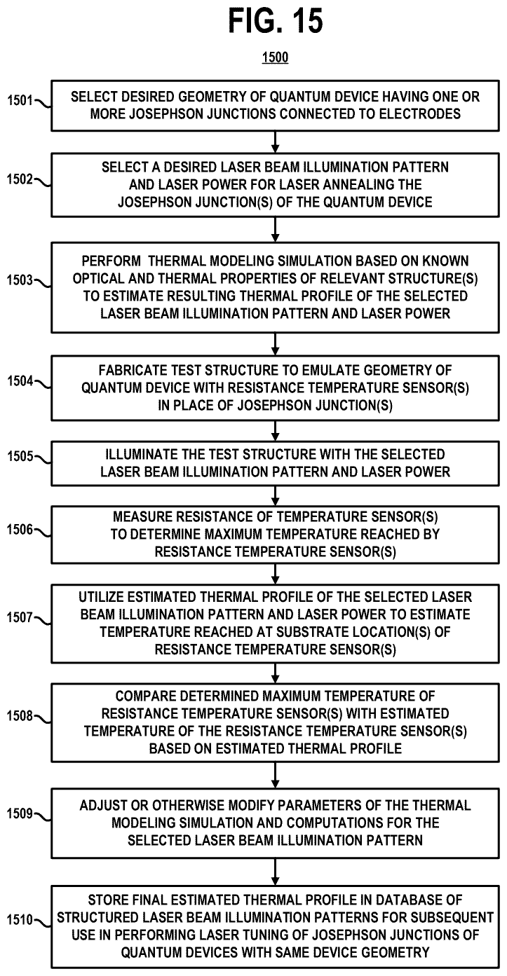

FIG. 15 illustrates a flow diagram of a method to compare and verify a simulated thermal profile and a corresponding measured thermal profile for a given structured laser beam illumination pattern at a given power level, according to an exemplary embodiment of the disclosure. In particular, FIG. 15 illustrates a process 1500 for determining a thermal profile of a given structured laser beam illumination pattern at a given laser power setting, which can be utilized to laser anneal one or more Josephson junctions of a given quantum device (e.g., qubit). An initial step comprises selecting a desired geometry of a quantum device having one or more Josephson junctions connected to electrodes (block 1501). For example, discussed above in conjunction with FIGS. 7A and 7B, a quantum device can be a superconducting qubit 710 having a single Josephson junction (FIG. 7A) or a superconducting qubit 810 having a SQUID comprising two Josephson junctions.

A next step of the process 1500 comprises selecting a desired laser beam illumination pattern and laser power setting for laser annealing the Josephson junction(s) of the given quantum device (block 1502). For example, a desired laser beam illumination pattern can be any of those shown in FIGS. 6C, 6D, and 9A-9G, depending on the geometry of the given quantum device.

A next step of the process 1500 comprises utilizing a thermal simulation and analysis tool to perform a thermal modeling simulation based on known optical and thermal properties of relevant structures of the quantum device (e.g., optical and thermal properties of the semiconductor substrate on which the quantum device is fabricated) to estimate a resulting thermal profile on a substrate surface due to the selected laser beam illumination pattern and laser power (block 1503). For example, the thermal modeling simulation is utilized to estimate a substrate temperature at regions of the substrate where the Josephson Junction(s) of the selected quantum device would be located.

The process 1500 further comprises fabricating one or more test structures on a test chip, which emulate the geometric structure (e.g., geometric size and layout) of the given quantum device, wherein each Josephson junction of the given quantum device represented by a resistance temperature sensor which emulate the placement and size of the given Josephson junction of the quantum device (block 1504). For example, as discussed above, FIGS. 7B and 8B schematically illustrate respective test structures 720 and 820 which emulate the respective geometric structures of the exemplary superconducting qubits 710 and 810 shown in FIGS. 7A and 8A.

A next step of the process 1500 comprises performing a process (similar to the calibration process 1000 of FIG. 10) which comprises, e.g., illuminating the test structure with the selected laser beam illumination pattern and laser power setting to thermally anneal the resistance temperature sensor(s) of the test structure (block 1505), and measure the resistance of each resistance temperature sensor of the test structure, and utilize the measured resistance of each resistance temperature sensor to determine a maximum temperature reached by each resistance temperature sensor as a result of the thermal annealing (block 1506).

The process 1500 then proceeds to utilize the results of the thermal modeling simulation (e.g., utilize the simulated thermal profile of the selected laser beam illumination pattern and laser power) to estimate the substrate temperature reached at the substrate location(s) of the resistance temperature sensor(s) of the test structure (block 1507). By way of example, the exemplary simulated thermal profile of the dual-spot laser beam illumination pattern 1310 as shown in FIGS. 13A and 13B can be utilized to determine the substrate temperature at the “center point” (coordinate (0,0) of the dual-spot laser beam illumination pattern 1310, where a given resistance temperature sensor would be located when, e.g., laser annealing the test structure 720 (FIG. 9A) using the dual-spot laser beam illumination pattern 1310.

A next step of the process 1500 comprises comparing the determined maximum temperature reached by each resistance temperature sensor of the test structure (based on the measure resistance of each resistance temperature sensor) with the estimated maximum substrate temperature reached at the substrate location(s) of the resistance temperature sensor(s) of the test structure based on the simulated thermal profile (block 1508). When the estimated maximum substrate temperature(s), which are based on the simulated thermal profile associated with the selected laser beam illumination pattern, are determined to correspond (within a specified margin of error threshold) to the determined maximum temperature(s) of the resistance temperature sensor(s) of the test structure, the given simulated thermal profile will be deemed accurate and valid, and stored (in association with the selected structured laser beam illumination pattern and laser power setting) in a database of structured laser beam illumination patterns (block 1510).

On the other hand, when the estimated maximum substrate temperature(s), which are based on the simulated thermal profile associated with the selected laser beam illumination pattern, are determined to not correspond (within a specified margin of error threshold) to the determined maximum temperature(s) of the resistance temperature sensor(s) of the test structure, the given simulated thermal profile will be deemed inaccurate. In this instance, the process 1500 proceeds by adjusting or otherwise modifying the parameters of the thermal modeling simulation associated with the selected laser beam illumination pattern so that newly estimated maximum substrate temperature(s) resulting from an updated simulated thermal profile correspond (within the specified margin of error threshold) to the determined maximum temperature(s) of the resistance temperature sensor(s) of the test structure (block 1509). When newly estimated maximum substrate temperature(s), which are based on an updated simulated thermal profile associated with the selected laser beam illumination pattern, are determined to correspond (within the specified margin of error threshold) to the determined maximum temperature(s) of the resistance temperature sensor(s) of the test structure, the updated simulated thermal profile will be deemed accurate, and the final (updated) simulated thermal profile will be stored (in association with the selected structured laser beam illumination pattern and laser power setting) in the database of structured laser beam illumination patterns for subsequent use in performing laser tuning of Josephson junctions of quantum devices having a device geometry correspond to the test structure (block 1510).

In instances where an accurate thermal profile is not achieved for a given structure laser beam illumination pattern, the process 1500 can proceed by modifying one or more parameters of the laser beam illumination pattern (e.g., modifying (i) spot pattern (e.g., single, double, triple, quad-spot, etc.), (ii) spot size, (iii) spot pitch, and/or (iv) spot profile (e.g., annular or Gaussian, etc.)) for laser annealing the given geometry of the quantum device and corresponding test structure. In other embodiments, the given geometry of the quantum device and corresponding test structure can be modified to be more compatible with the selected laser beam illumination pattern.

It is to be noted while exemplary process 1500 of FIG. 15 is discussed in the context of generating a given thermal profile for a given structured laser beam illumination pattern and given laser power setting, the same process 1500 can be repeated to generate thermal profiles for (i) the same structured laser beam illumination pattern at other laser power levels, and (ii) a plurality of different structured laser beam illumination patterns with unique combinations of laser beam illumination pattern parameters (e.g., (i) spot pattern (e.g., single, double, triple, quad-spot, etc.), (ii) spot size, (iii) spot pitch, and/or (iv) spot profile (e.g., annular or Gaussian, etc.)) and for a variety of unique test structures with different geometric configurations of resistance temperature sensors that emulate Josephson junctions of quantum devices.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

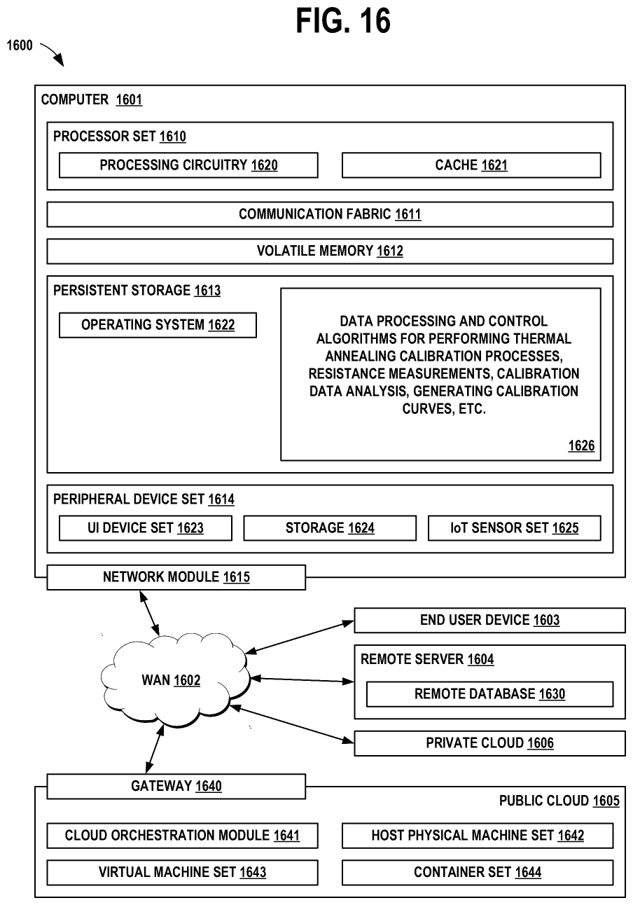

As noted above, FIG. 16 schematically illustrates an exemplary architecture of a computing environment 1600 for implementing a control system of a thermal annealing system, according to an exemplary embodiment of the disclosure. The computing environment 1600 of FIG. 16 contains an example of an environment for the execution of at least some of the computer code (block 1626) comprising data processing and control algorithms for performing thermal annealing calibration processes, resistance measurement of resistance temperature sensors, calibration data analysis to generate calibration curves, and other computer automated control and data processing operations as discussed herein for performing the exemplary methods shown or otherwise explained in conjunction with certain Figures. In addition to block 1626, computing environment 1600 includes, for example, computer 1601, wide area network (WAN) 1602, end user device (EUD) 1603, remote server 1604, public cloud 1605, and private cloud 1606. In this embodiment, computer 1601 includes processor set 1610 (including processing circuitry 1620 and cache 1621), communication fabric 1611, volatile memory 1612, persistent storage 1613 (including operating system 1622 and block 1626, as identified above), peripheral device set 1614 (including user interface (UI), device set 1623, storage 1624, and Internet of Things (IOT) sensor set 1625), and network module 1615. Remote server 1604 includes remote database 1630. Public cloud 1605 includes gateway 1640, cloud orchestration module 1641, host physical machine set 1642, virtual machine set 1643, and container set 1644.

Computer 1601 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1630. As is well understood in the art of computer technology, and depending upon the technology, performance of a computer-implemented method may be distributed among multiple computers and/or between multiple locations. On the other hand, in this presentation of computing environment 1600, detailed discussion is focused on a single computer, specifically computer 1601, to keep the presentation as simple as possible. Computer 1601 may be located in a cloud, even though it is not shown in a cloud in FIG. 16. On the other hand, computer 1601 is not required to be in a cloud except to any extent as may be affirmatively indicated.

Processor set 1610 includes one, or more, computer processors of any type now known or to be developed in the future. Processing circuitry 1620 may be distributed over multiple packages, for example, multiple, coordinated integrated circuit chips. Processing circuitry 1620 may implement multiple processor threads and/or multiple processor cores. Cache 1621 is memory that is located in the processor chip package(s) and is typically used for data or code that should be available for rapid access by the threads or cores running on processor set 1610. Cache memories are typically organized into multiple levels depending upon relative proximity to the processing circuitry. Alternatively, some, or all, of the cache for the processor set may be located “off chip.” In some computing environments, processor set 1610 may be designed for working with qubits and performing quantum computing.

Computer readable program instructions are typically loaded onto computer 1601 to cause a series of operational steps to be performed by processor set 1610 of computer 1601 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1621 and the other storage media discussed below. The program instructions, and associated data, are accessed by processor set 1610 to control and direct performance of the inventive methods. In computing environment 1600, at least some of the instructions for performing the inventive methods may be stored in block 1626 in persistent storage 1613.

Communication fabric 1611 comprises the signal conduction paths that allow the various components of computer 1601 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1612 is any type of volatile memory now known or to be developed in the future. Examples include dynamic type random access memory (RAM) or static type RAM. Typically, the volatile memory is characterized by random access, but this is not required unless affirmatively indicated. In computer 1601, the volatile memory 1612 is located in a single package and is internal to computer 1601, but, alternatively or additionally, the volatile memory may be distributed over multiple packages and/or located externally with respect to computer 1601.

Persistent storage 1613 is any form of non-volatile storage for computers that is now known or to be developed in the future. The non-volatility of this storage means that the stored data is maintained regardless of whether power is being supplied to computer 1601 and/or directly to persistent storage 1613. Persistent storage 1613 may be a read only memory (ROM), but typically at least a portion of the persistent storage allows writing of data, deletion of data and re-writing of data. Some familiar forms of persistent storage include magnetic disks and solid-state storage devices. Operating system 1622 may take several forms, such as various known proprietary operating systems or open source Portable Operating System Interface type operating systems that employ a kernel. The code included in block 1626 typically includes at least some of the computer code involved in performing the inventive methods.

Peripheral device set 1614 includes the set of peripheral devices of computer 1601. Data communication connections between the peripheral devices and the other components of computer 1601 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1623 may include components such as a display screen, speaker, microphone, wearable devices (such as goggles and smart watches), keyboard, mouse, printer, touchpad, game controllers, and haptic devices. Storage 1624 is external storage, such as an external hard drive, or insertable storage, such as an SD card. Storage 1624 may be persistent and/or volatile. In some embodiments, storage 1624 may take the form of a quantum computing storage device for storing data in the form of qubits. In embodiments where computer 1601 is required to have a large amount of storage (for example, where computer 1601 locally stores and manages a large database) then this storage may be provided by peripheral storage devices designed for storing very large amounts of data, such as a storage area network (SAN) that is shared by multiple, geographically distributed computers. IoT sensor set 1625 is made up of sensors that can be used in Internet of Things applications. For example, one sensor may be a thermometer and another sensor may be a motion detector.

Network module 1615 is the collection of computer software, hardware, and firmware that allows computer 1601 to communicate with other computers through WAN 1602. Network module 1615 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1615 arc performed on the same physical hardware device. In other embodiments (for example, embodiments that utilize software-defined networking (SDN)), the control functions and the forwarding functions of network module 1615 are performed on physically separate devices, such that the control functions manage several different network hardware devices. Computer readable program instructions for performing the exemplary inventive methods can typically be downloaded to computer 1601 from an external computer or external storage device through a network adapter card or network interface included in network module 1615.

WAN 1602 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1603 is any computer system that is used and controlled by an end user (for example, a customer of an enterprise that operates computer 1601), and may take any of the forms discussed above in connection with computer 1601. EUD 1603 typically receives helpful and useful data from the operations of computer 1601. For example, in a hypothetical case where computer 1601 is designed to provide a recommendation to an end user, this recommendation would typically be communicated from network module 1615 of computer 1601 through WAN 1602 to EUD 1603. In this way, EUD 1603 can display, or otherwise present, the recommendation to an end user. In some embodiments, EUD 1603 may be a client device, such as thin client, heavy client, mainframe computer, desktop computer and so on.

Remote server 1604 is any computer system that serves at least some data and/or functionality to computer 1601. Remote server 1604 may be controlled and used by the same entity that operates computer 1601. Remote server 1604 represents the machine(s) that collect and store helpful and useful data for use by other computers, such as computer 1601. For example, in a hypothetical case where computer 1601 is designed and programmed to provide a recommendation based on historical data, then this historical data may be provided to computer 1601 from remote database 1630 of remote server 1604.

Public cloud 1605 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1605 is performed by the computer hardware and/or software of cloud orchestration module 1641. The computing resources provided by public cloud 1605 are typically implemented by virtual computing environments that run on various computers making up the computers of host physical machine set 1642, which is the universe of physical computers in and/or available to public cloud 1605. The virtual computing environments (VCEs) typically take the form of virtual machines from virtual machine set 1643 and/or containers from container set 1644. It is understood that these VCEs may be stored as images and may be transferred among and between the various physical machine hosts, either as images or after instantiation of the VCE. Cloud orchestration module 1641 manages the transfer and storage of images, deploys new instantiations of VCEs and manages active instantiations of VCE deployments. Gateway 1640 is the collection of computer software, hardware, and firmware that allows public cloud 1605 to communicate through WAN 1602.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1606 is similar to public cloud 1605, except that the computing resources are only available for use by a single enterprise. While private cloud 1606 is depicted as being in communication with WAN 1602, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1605 and private cloud 1606 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
a substrate; and
a resistance temperature sensor disposed on the substrate, the resistance temperature sensor comprising a stack of alternating metal layers of a first metal and a second metal, wherein the first metal and the second metal are different types of metals.

2. The device of claim 1, wherein:
the metal layers of the first metal have a first thickness;
the metal layers of the second metal have a second thickness; and
the first thickness is less than the second thickness.

3. The device of claim 1, wherein:
the first metal comprises titanium; and
the second metal comprises platinum.

4. The device of claim 1, wherein:
the resistance temperature sensor comprises a resistive wire;
the resistive wire comprises a first wire portion, a second wire portion, and a third wire portion disposed between the first wire portion and the second wire portion;
the first wire portion and the second wire portion have a first width;
the third wire portion comprises a second width, which is less than the first width.

5. The device of claim 1, wherein the resistance temperature sensor comprises a negative temperature coefficient in which an electrical resistance of the resistance temperature sensor decreases as the resistance temperature sensor is heated at increasing temperatures.

6. The device of claim 1, wherein the resistance temperature sensor comprises at least three metal layers of the first metal and three metal layers of the second metal.

7. The device of claim 1, wherein:
the resistance temperature sensor is a component of a test structure that is disposed on the substrate;
the test structure emulates a geometric structure of a quantum device comprising a Josephson junction; and
the resistance temperature sensor emulates a size and placement of the Josephson junction of the quantum device.

8. The device of claim 7, wherein the quantum device comprises a superconducting quantum bit.

9. A method, comprising:
selecting a laser beam illumination pattern and a first laser power setting to irradiate a test structure disposed on a substrate, wherein the test structure emulates a geometric structure of a quantum device comprising a Josephson junction, and comprises a resistance temperature sensor that emulates a size and placement of the Josephson junction of the quantum device;
performing a first thermal anneal process by irradiating the test structure using the selected laser beam illumination pattern at the first laser power setting to thermally anneal the resistance temperature sensor;
measuring a first resistance of the resistance temperature sensor subsequent to the first thermal anneal process; and
determining a maximum temperature to which the resistance temperature sensor was exposed as a result of the first thermal anneal process, based on the measured first resistance.

10. The method of claim 9, further comprising:
increasing a laser power of the selected laser beam illumination pattern to a second laser power setting;
performing a second thermal anneal process by irradiating the test structure using the selected laser beam illumination pattern at the second laser power setting to thermally anneal the resistance temperature sensor;
measuring a second resistance of the resistance temperature sensor subsequent to the second thermal anneal process; and
determining a maximum temperature to which the resistance temperature sensor was exposed as a result of the second thermal anneal process, based on the measured second resistance.

11. The method of claim 10, further comprising utilizing at least the measured first resistance and the measured second resistance to generate a calibration curve that represents a resistance of the resistance temperature sensor as a function of the laser power of the selected laser beam illumination pattern.

12. The method of claim 11, further comprising persistently storing the calibration curve for subsequent use in configuring a laser annealing process to laser anneal a quantum device that is emulated by the test structure.

13. The method of claim 9, wherein selecting the laser beam illumination pattern comprises selecting a combination of parameters for generating the laser beam illumination pattern, the parameters comprising: a laser spot pattern; a laser spot size; a laser spot pitch; and a laser spot profile.

14. The method of claim 13, wherein:
the laser spot pattern comprises one of a single-spot pattern, a dual-spot pattern, a triple-spot pattern, and a quad-spot pattern; and
the laser spot profile comprises one of an annular profile and a Gaussian profile.

15. The method of claim 10, wherein the test structure emulates a geometric structure of superconducting qubit comprising at least one Josephson junction.

16. A method, comprising:
selecting a laser beam illumination pattern and a laser power setting to irradiate a test structure disposed on a substrate, wherein the test structure emulates a geometric structure of a quantum device comprising a Josephson junction, and comprises a resistance temperature sensor that emulates a size and placement of the Josephson junction of the quantum device;
performing a thermal anneal process by irradiating the test structure using the selected laser beam illumination pattern at the laser power setting to thermally anneal the resistance temperature sensor;
measuring a resistance of the resistance temperature sensor subsequent to the thermal anneal process;
determining a maximum temperature to which the resistance temperature sensor was exposed as a result of the thermal anneal process, based on the measured resistance;
obtaining a simulated thermal profile which represents a temperature gradient of a substrate surface irradiated using the selected laser beam illumination pattern and the laser power setting;
utilizing the simulated thermal profile to estimate a maximum temperature at a region of the substrate where the resistance temperature sensor of the test structure is located;
comparing the estimated maximum temperature with the determined maximum temperature; and
determining an accuracy of the simulated thermal profile, based on a result of comparing the estimated maximum temperature with the determined maximum temperature.

17. The method of claim 16, further comprising persistently storing the simulated thermal profile in association with the selected laser beam illumination pattern and the laser power setting for subsequent use in configuring a laser annealing process to laser anneal a quantum device that is emulated by the test structure.

18. The method of claim 16, further comprising obtaining an updated simulated thermal profile which represents a temperature gradient of a substrate surface irradiated using the selected laser beam illumination pattern and the laser power setting, based on at least one updated thermal model parameter.

19. The method of claim 16, wherein:
selecting the laser beam illumination pattern comprises selecting a combination of parameters for generating the laser beam illumination pattern, the parameters comprising: a laser spot pattern; a laser spot size; a laser spot pitch; and a laser spot profile;
the laser spot pattern comprises one of a single-spot pattern, a dual-spot pattern, a triple-spot pattern, and a quad-spot pattern; and
the laser spot profile comprises one of an annular profile and a Gaussian profile.

20. The method of claim 16, wherein the test structure emulates a geometric structure of superconducting qubit comprising at least one Josephson junction.
